(19) United States
(12) Patent Application Publication
(10) Pub. No.: US 2023/0104772 A1
(43) Pub. Date: Apr. 6, 2023

(54) ELECTRONIC DEVICE

(71) Applicant: Samsung Display Co,. Ltd., Yongin-si (KR)

(72) Inventors: HYEONSIK KIM, Yongin-si (KR); TAEKYUNG AHN, Yongin-si (KR); DAE-YOUNG LEE, Seoul (KR); SANGWOO KIM, Seoul (KR); SANGHWAN CHO, Suwon-si (KR)

(21) Appl. No.: 17/939,132

(22) Filed: Sep. 7, 2022

(30) Foreign Application Priority Data
Oct. 1, 2021 (KR) 10-2021-0131159

(51) Int. Cl. H01L 27/32

(52) U.S. Cl. CPC H01L 27/3269; H01L 27/3246; H01L 27/323; H01L 27/3262

(57) ABSTRACT

An electronic device includes a base layer. A pixel definition layer is disposed on the base layer. The pixel definition layer includes a first opening extending therethrough and a second opening extending therethrough. A light emitting element is disposed on the base layer and overlaps the first opening. A light sensing element is disposed on the base layer and overlaps the second opening. The light sensing element comprises a photodiode and a conductive pattern that directly contacts the photodiode. A pixel transistor is connected to the light emitting element. A sensing transistor is connected to the light sensing element. The light sensing element is disposed between a layer that the pixel transistor is disposed and a layer that the light emitting element is disposed.

This application claims priority under 35 U.S.C. § 119 to Korean Patent Application No. 10-2021-0131159, filed on Oct. 1, 2021 in the Korean Intellectual Property Office, the disclosure of which is incorporated by reference in its entirety herein.

### 1. TECHNICAL FIELD

The present disclosure relates to an electronic device. More particularly, the present disclosure relates to an electronic device capable of sensing biometric information.

### 2. DISCUSSION OF RELATED ART

Various electronic devices include display devices to provide image information to the user. Additionally, many electronic devices provide various functions to organically communicate with a user, such as sensing a user's input. In particular, recent electronic devices have a function to detect a user's fingerprint.

The electronic device may detect a user's fingerprint utilizing a capacitive method that senses a variation in capacitance formed between electrodes, an optical method that senses an incident light using an optical sensor, or an ultrasonic method that senses a vibration using a piezoelectric material. In embodiments in which the optical method using the optical sensor is utilized, noises generated by the external light may be blocked to increase the performance of the fingerprint recognition.

### SUMMARY

Embodiments of the present disclosure provide an electronic device including a display panel provided with a sensor to recognize biometric information.

According to embodiments of the present disclosure:, an electronic device includes a base layer. A pixel definition layer is disposed on the base layer. The pixel definition layer includes a first opening and a second opening. A light emitting element is disposed on the base layer and overlaps the first opening. A light sensing element is disposed on the base layer and overlaps the second opening. The light sensing element comprises a photodiode and a conductive pattern that directly contacts the photodiode. A pixel transistor is connected to the light emitting element. A sensing transistor is connected to the light sensing element. The light sensing element is disposed between a layer that the pixel transistor is disposed and a layer that the light emitting element is disposed.

In an embodiment, the conductive pattern includes a transparent conductive oxide.

In an embodiment, the pixel transistor includes a first semiconductor pattern and a first electrode, and the sensing transistor includes a semiconductor pattern disposed on a same layer as a layer that the first semiconductor pattern is disposed and an electrode disposed on a same layer as a layer that the first electrode is disposed.

In an embodiment, the electronic device further includes a first conductive pattern connected to the first semiconductor pattern and a second conductive pattern connected to a semiconductor pattern of the sensing transistor and disposed on a same layer as a layer that the first conductive pattern is disposed, and the photodiode directly contacts the second conductive pattern.

In an embodiment, the electronic device further includes a second pixel transistor electrically connected to the pixel transistor. The second pixel transistor includes a second semiconductor pattern and a second electrode, and the second semiconductor pattern includes a material different from a material of the first semiconductor pattern.

In an embodiment, the second semiconductor pattern and the second electrode are disposed between the layer that the first electrode is disposed and the layer that the first conductive pattern is disposed.

In an embodiment, the electronic device further includes a metal pattern disposed under the second semiconductor pattern, and the metal pattern is disposed on a same layer as the layer that the first electrode is disposed.

In an embodiment, the second semiconductor pattern includes an oxide semiconductor, and the first semiconductor pattern includes polysilicon.

In an embodiment, the electronic device further includes a third conductive pattern disposed between the first conductive pattern and the light emitting element and connected to the first conductive pattern and the light emitting element and a fourth conductive pattern connected to the light sensing element. The third conductive pattern is disposed on a same layer as a layer that the fourth conductive pattern is disposed.

In an embodiment, the electronic device further includes a color filter layer disposed on the light emitting element and including a black matrix. The black matrix includes openings extending therethrough to respectively overlap the first opening and the second opening

In an embodiment, the pixel definition layer includes a dye or a pigment.

In an embodiment, the electronic device further includes an input sensing layer disposed between the color filter layer and the light emitting element.

In an embodiment, the input sensing layer comprises mesh lines connected to each other, and the mesh lines overlap the pixel definition layer when viewed in a plane.

According to an embodiment of the present disclosure, an electronic device includes a base layer. A circuit layer is disposed on the base layer and comprises a pixel transistor, a light sensing element, and a sensing transistor connected to the light sensing element. A pixel definition layer is disposed on the circuit layer and comprises a dye or a pigment. The pixel definition layer includes a first opening extending therethrough and a second opening extending therethrough and spaced apart from the first opening. The second opening overlaps the light sensing element. A light emitting element overlaps the first opening. An encapsulation layer is disposed on the light emitting element. A color filter layer is disposed on the encapsulation layer and comprises a black matrix. The light sensing element comprises a photodiode and a transparent electrode disposed on the photodiode.

In an embodiment, the pixel transistor includes a semiconductor pattern and an electrode, and the sensing transistor includes a semiconductor pattern disposed on a same layer as a layer that the semiconductor pattern of the pixel transistor is disposed and an electrode disposed on a same layer as a layer that the electrode of the pixel transistor is disposed.

In an embodiment, the electronic device further includes a conductive pattern connected to the semiconductor pattern of the sensing transistor, and the photodiode is disposed on the conductive pattern and directly contacts the conductive pattern.

In an embodiment, the electronic device further includes a second pixel transistor spaced apart from the pixel transistor and connected to the light emitting element. The second pixel transistor includes a second semiconductor pattern and a second electrode, that are disposed on layers respectively different from layers that the semiconductor pattern and the electrode are disposed.

In an embodiment, the second pixel transistor includes an oxide semiconductor.

In an embodiment, the pixel transistor and the sensing transistor include polysilicon.

In an embodiment, the electronic device further includes an input sensing layer disposed between the color filter layer and the encapsulation layer.

According to the above, the light sensing element including the photodiode is mounted in the display panel. Accordingly, the function of sensing the biometric information of a user is built in the display panel, and thus, the user's convenience is increased.

### BRIFF DESCRIPTION OF THE DRAWINGS

The above and other advantages of the present disclosure will become readily apparent by reference to the following detailed description when considered in conjunction with the accompanying drawings wherein:

FIG. 1 is a perspective view of an electronic device according to an embodiment of the present disclosure;

FIG. 2 is a cross-sectional view of an electronic device according to an embodiment of the present disclosure;

FIG. 3 is a block diagram of an electronic device according to an embodiment of the present disclosure;

FIG. 4 is an enlarged plan view of a portion of a display panel according to an embodiment of the present disclosure;

FIG. 5 is a circuit diagram of a pixel driving circuit and a sensor driving circuit according to an embodiment of the present disclosure;

FIG. 6 is a cross-sectional view of an electronic device according to an embodiment of the present disclosure;

FIG. 7 is a cross-sectional view of an electronic device according to an embodiment of the present disclosure; and

FIGS. 8A to 8M are cross-sectional views of a method of manufacturing an electronic device according to embodiments of the present disclosure.

### DETAILED DESCRIPTION OF EMBODIMENTS

In the present disclosure, it will be understood that when an element (or area, layer, or portion) is referred to as being “on”, “connected to” or “coupled to” another element or layer, it can be directly on, connected or coupled to the other element or layer or intervening elements or layers may be present. When an element (or area, layer, or portion) is referred to as being “directly on”, “directly connected to” or “directly coupled to” another element or layer, no intervening elements or layers may be present.

Like numerals refer to like elements throughout. In the drawings, the thickness, ratio, and dimension of components may be exaggerated for effective description of the technical content.

As used herein, the term “and/or” includes any and all combinations of one or more of the associated listed items.

It will be understood that, although the terms first, second, etc., may be used herein to describe various elements, these elements should not be limited by these terms. These terms are only used to distinguish one element from another element. Thus, a first element discussed below could be termed a second element without departing fr©m the teachings of the present disclosure. As used herein, the singular forms, “a”, “an” and “the” are intended to include the plural forms as well, unless the context clearly indicates otherwise.

Spatially relative terms, such as “beneath”, “below”, “lower”, “above”, “upper” and the like, may be used herein for ease of description to describe one element or feature's relationship to another element(s) or feature(s) as illustrated in the figures.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

It will be further understood that the terms “includes” and/or “including”, when used in this specification, specify the presence of stated features, integers, steps, operations, elements, and/or components, but do not preclude the presence or addition of one or more other features, integers, steps, operations, elements, components, and/or groups thereof.

Hereinafter, the present disclosure will be explained in detail with reference to the accompanying drawings.

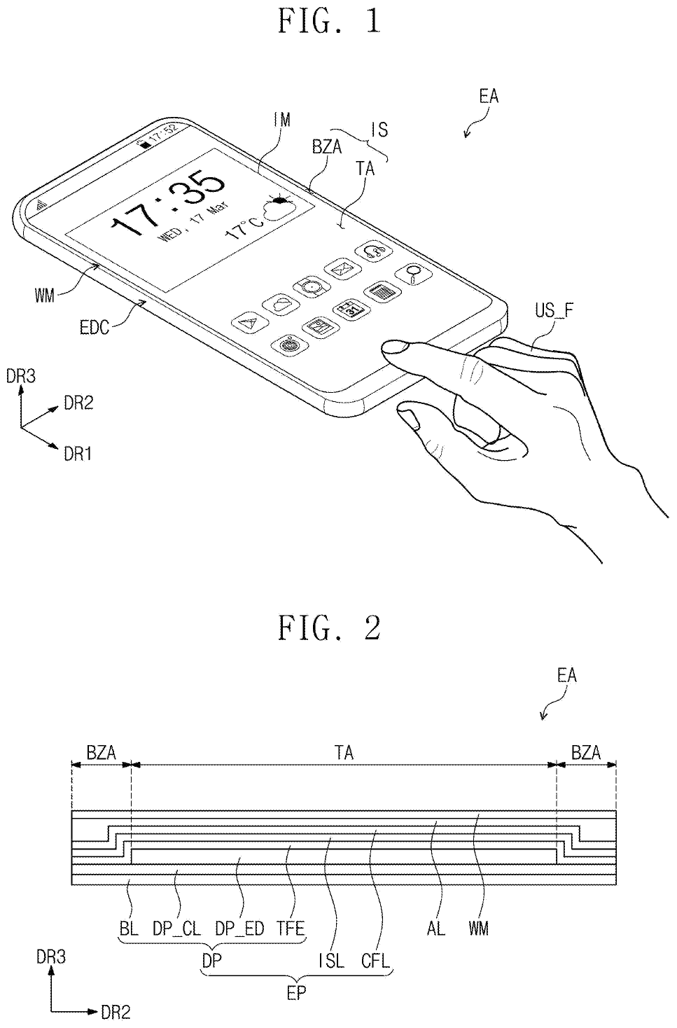

FIG. 1 is a perspective view of an electronic device EA according to an embodiment of the present disclosure, and FIG. 2 is a cross-sectional view of the electronic device EA according to an embodiment of the present disclosure.

Referring to FIGS. 1 and 2, the electronic device EA may be a device activated in response to electrical signals. As an example, the electronic device EA may be applied to an electronic item, such as a smartphone, a smart watch, a tablet computer, a notebook computer, a computer, a smart television set, etc. In the present embodiment, a smartphone will be described as a representative example of the electronic device I.A.

The electronic device EA may display images IM on a front surface IS thereof. The front surface IS may be a plane defined by a first direction DR1 and a second direction DR2 crossing the first direction DR1. In the present embodiment, a third direction DR3 may cross each of the first direction DR1 and the second direction DR2 and may be defined as a thickness direction of the electronic device EA.

The front surface IS may be divided into a transmission area TA and a bezel area BZA. The images IM may be displayed through the transmission area TA. A user may view the images IM through the transmission area TA. For example, in an embodiment of FIG. 1, the images IM are software application icons and a clock, temperature and calendar window However embodiments of the present disclosure are not necessarily limited thereto and the images IM may be various different subject matters. In an embodiment as shown in FIG. 1, the transmission area TA may have a quadrangular shape with rounded vertices. However, this is merely one example, and the transmission area TA may have a variety of shapes and should not necessarily be particularly limited thereto.

The bezel area BZA may be defined adjacent to the transmission area TA. The bezel area BZA may have a predetermined color. The bezel area BZA may surround the transmission area TA (e.g., in the first and second directions DR1, DR2). Accordingly, the shape of the transmission area. TA may be defined by the bezel area BZA. However, this is merely one example and the bezel area BZA may not be surrounded on at least one side by the bezel area BZA. For example, the bezel area BZA may be disposed adjacent to only one side of the transmission area TA or may be omitted.

In an embodiment, the electronic device EA may sense an external input applied to the front surface IS. In an embodiment of FIG. 1, a user's hand US_F is shown as the external input, however, this is merely one example. The external input may include various types of inputs provided from the outside of the electronic device EA. As an example, the external input may include various external inputs, such as an electronic pen, light, heat, or pressure as well as a touch input by a user's body part, e.g., a hand of a user US_F.

In addition, the external input may include an external input (e.g., a hovering input) in proximity to or approaching close to the electronic device EA at a predetermined distance as well as a direct touch on the electronic device EA, A position at which the external input is sensed is shown on the front surface IS as a representative example, however, the position does not necessarily coincide with the area where the image is displayed, and the position may be changed in various ways.

In addition, the electronic device EA may sense user's biometric information. The biometric information may include various information detected through the user's body, such as a fingerprint, palm lines, and a body temperature. In an embodiment as shown in FIG. 1, the biometric information may be the fingerprint sensed through the user's hand US_F. In an embodiment, an area where the biometric information is sensed may be provided over the entire front surface IS, however, this is merely one example. According to an embodiment, the area where the biometric information is sensed in the electronic device EA may be provided at a position different from a sensing area of the external input, however, it should not necessarily be particularly limited thereto.

Referring to an embodiment of FIG. 2, the electronic device EA may include a window WM, an electronic panel EP, and a housing EDC. In an embodiment, the window WM and the housing EDC may be coupled to each other to provide an external appearance of the electronic device EA.

A front surface of the window WM may define the front surface IS of the electronic device EA. The window WM may include an optically transparent insulating material. As an example, in an embodiment, the window WM may include a glass or plastic material. The window WM may have a single-layer or multi-layer structure. As an example, the window WM may include a plurality of plastic films attached to each other by an adhesive or a glass substrate and a plastic film attached to the glass substrate by an adhesive.

The electronic panel EP may include a display panel DP and an input sensing layer ISL. The display panel DP may display the images IM in response to the electrical signals, and the input sensing layer ISL may sense the external input applied thereto from the outside. The external input may be provided in various forms.

The display panel DP according to an embodiment of the present disclosure may be a light-emitting type display panel, however, it should not necessarily be particularly limited thereto. For instance, the display panel DP may be an organic light emitting display panel, an inorganic light emitting display panel, or a quantum dot light emitting display panel. A light emitting layer of the organic light emitting display panel may include an organic light emitting material. A light emitting layer of the inorganic light emitting display panel may include an inorganic light emitting material. A light emitting layer of the quantum dot light emitting display panel may include a quantum dot and a quantum rod. Hereinafter, the organic light emitting display panel will be described as a representative example of the display panel DP.

The display panel DP may include a base layer BL, a circuit layer DP_CL, an element layer DP_ED, and an encapsulation layer TFE, In an embodiment, the display panel DP may be a flexible display panel. Accordingly, the display panel DP may be folded or rolled. However, this is merely one example. According to an embodiment, the display panel DP may be a rigid display panel or a stretchable display panel, and it should not necessarily be particularly limited thereto.

In an embodiment, the base layer BL may include a synthetic resin layer. The synthetic resin layer may be a polyimide-based resin layer, however, a material for the synthetic resin layer should not necessarily be particularly limited thereto. In addition, the base layer BL may include a glass substrate, a metal substrate, or an organic/inorganic composite substrate,

The circuit layer DP_CL may be disposed on the base layer BL (e.g., directly thereon in the third direction DR3). The circuit layer DP_CL may include at least one insulating layer and a circuit element. Hereinafter, the insulating layer included in the circuit layer DP_CL is referred to as an interlayer insulating layer. The interlayer insulating layer may include at least one intermediate inorganic layer and at least one intermediate organic layer. The circuit element may include a pixel driving circuit included in each of a plurality of pixels displaying the image and a sensor driving circuit included in each of a plurality of sensors to sense external information, For example, the external information may be biometric information.

In an embodiment, the circuit layer DP_CL may include a sensor. The sensor may be, but is not necessarily limited to, a fingerprint recognition sensor, a proximity sensor, or an iris recognition sensor. In addition, the sensor may be an optical sensor recognizing the biometric information in an optical method. An optical fingerprint sensor may sense a light reflected by the user's fingerprint. As an example, the optical fingerprint sensor may include a photodiode. The circuit layer DP_CL may further include signal lines connected to the pixel driving circuit and the sensor driving circuit.

The element layer DP_ED may include a light emitting element included in each of the pixels. The light emitting element may include an organic light emitting element, an inorganic light emitting element, or a quantum dot light emitting element.

The encapsulation layer TFE may encapsulate the element layer DP_ED. In an embodiment, the encapsulation layer TFE may include at least one organic layer and at least one inorganic layer. The inorganic layer may include an inorganic material and may protect the element layer DILED from moisture and oxygen. For example, the inorganic layer may include a silicon nitride layer, a silicon oxynitride layer, a silicon oxide layer, a titanium oxide layer, or an aluminumoxide layer, however, it should not be necessarily limited thereto or thereby. The organic layer may include an organic material and may protect the element layer DP_ED from a foreign substance such as dust particles.

The input sensing layer 1SL may be formed on the display panel DP. The input sensing layer ISL may be disposed directly on the encapsulation layer TFE. According to an embodiment, the input sensing layer ISL may be formed on the display panel DP through successive processes. For example, in an embodiment in which the input sensing layer ISL is disposed directly on the display panel DP, an adhesive film may not be disposed between the input sensing layer ISL and the encapsulation layer TFE. However, alternatively, an inner adhesive film may be disposed between the input sensing layer 1SL and the display panel DP. In this embodiment, the input sensing layer ISL may not be manufactured with the display panel DP through the successive processes and may be attached to an upper surface of the display panel DP by the inner adhesive film after being manufactured separately from the display panel DP.

The input sensing layer ISL may sense the external input, such as a user's touch, may convert the external input to a predetermined input signal, and may provide the input signal to the display panel DP. The input sensing layer 1SL may include a plurality of sensing electrodes to sense the external input. The sensing electrodes may sense the external input by a capacitance method. The display panel DP may receive the input signal from the input sensing layer ISL and may generate the image corresponding to the input signal. However, embodiments of the present disclosure are not necessarily limited thereto. For example, in an embodiment, the input sensing layer ISL may be omitted from the electronic device.

A color filter layer CFL may be disposed on the display panel DP. According to an embodiment, the color filter layer CFL may be disposed on the input sensing layer ISL (e.g., directly thereon in the third direction DR3). The color filter layer CFL may include a plurality of color filters and a black matrix, however, this is merely one example. According to an embodiment, the color filter layer CFL may be disposed between the display panel DP and the input sensing layer 1SL or may be omitted.

According to an embodiment, the electronic device EA may further include an adhesive layer AL. The window WM may be attached to the input sensing layer ISL by the adhesive layer AL. The adhesive layer AL may include an optical clear adhesive, an optically clear adhesive resin, or a pressure sensitive adhesive (PSA).

The housing EDC may be coupled to the window WM. The housing EDC may be coupled to the window WM to provide a predetermined inner space. The electronic panel EP may be accommodated in the inner space. In an embodiment, the housing EDC may include a material with a relatively high rigidity. For example, the housing EDC may include a glass, plastic, or metal material or a plurality of frames and/or plates of combinations thereof. The housing EDC may stably protect components of the electronic device EA accommodated in the inner space from external impacts. In an embodiment, a battery module may be disposed in the inner space of the housing EDC in addition to the electronic device EA shown in FIG. 2 to supply a power necessary for an overall operation of the electronic device EA.

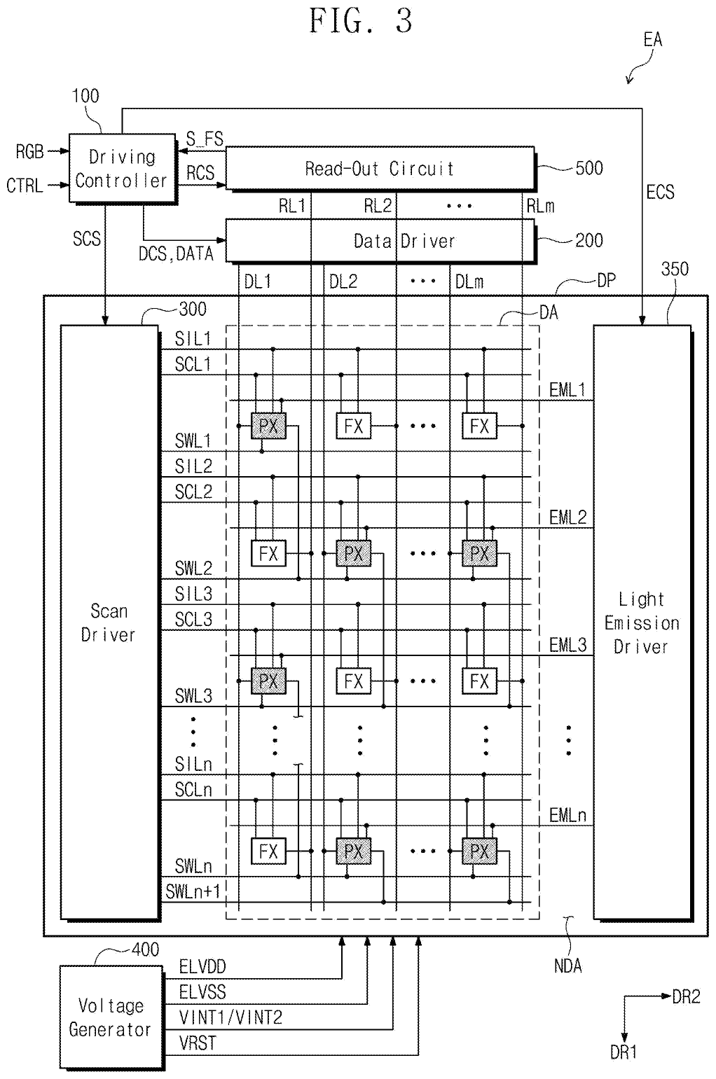

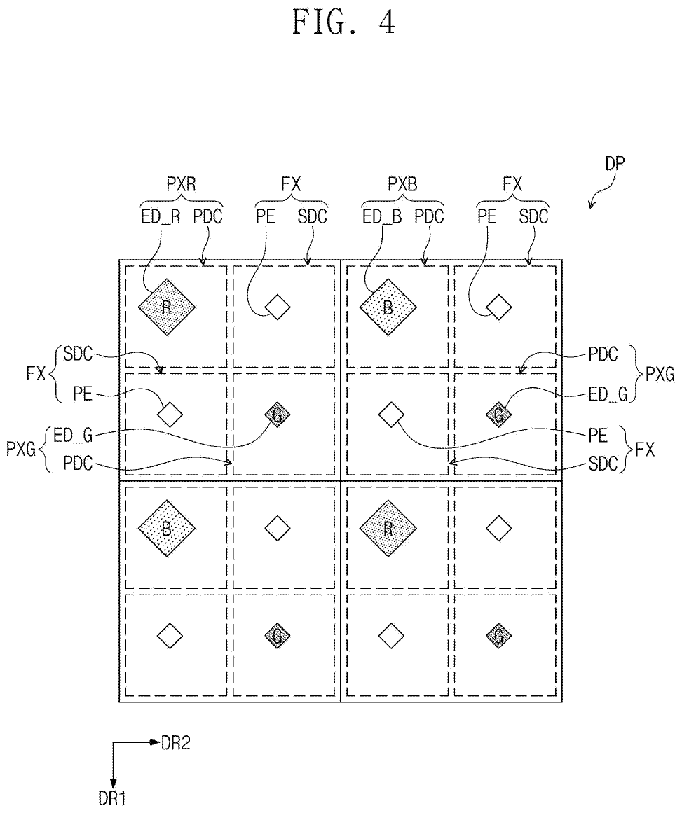

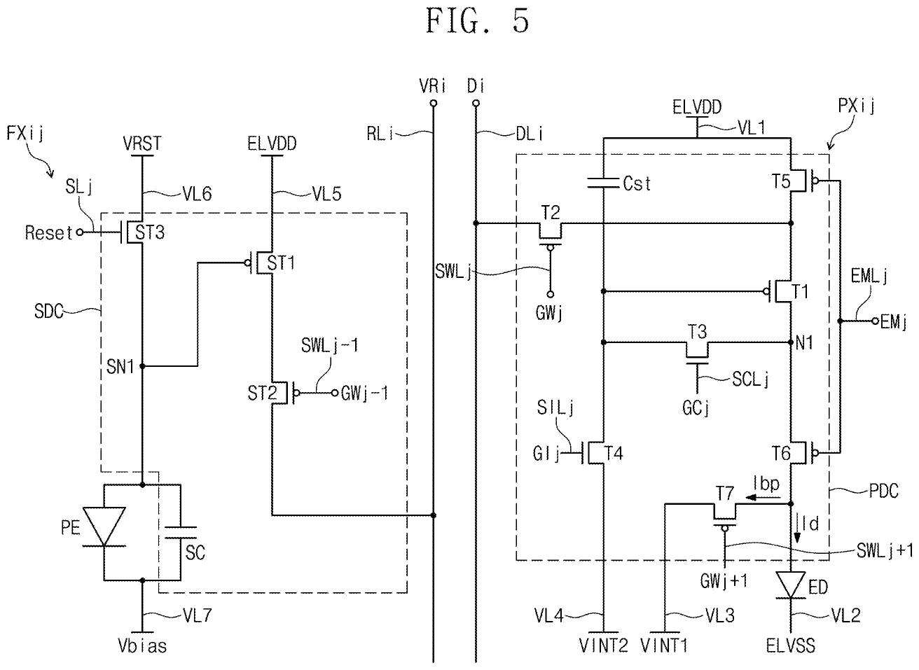

FIG. 3 is a block diagram of the electronic device EA according to an embodiment of the present disclosure, and FIG. 4 is an enlarged plan view of a portion of the display panel DP according to an embodiment of the present disclosure.

Referring to FIG. 3, the electronic device EA may include the display panel DP, a panel driver, and a driving controller 100. As an example, the panel driver may include a data driver 200, a scan driver 300, a light emission driver 350, a voltage generator 400, and a read-out circuit 500.

The driving controller 100 may receive an image signal RGB and control signals CTRL. The driving controller 100 may convert a data format of the image signal RGB to a data format appropriate to an interface between the data driver 200 and the driving controller 100 to generate image data signal DATA. The driving controller 100 may generate a first control signal SCS, a second control signal ECS, a third control signal DCS, and a fourth control signal RCS.

The data driver 200 may receive the third control signal DCS and the image data signal DATA from the driving controller 100. The data driver 200 may convert the image data signal DATA to data signals and may output the data signals to a plurality of data lines DL1 to DLm described later. The data signals may be analog voltages corresponding to grayscale values of the image data signal DATA.

The scan driver 300 may receive the first control signal SCS from the driving controller 100. The scan driver 300 may output scan signals to scan lines in response to the first control signal SCS.

The voltage generator 400 may generate voltages required to operate the display panel DP. In an embodiment of FIG. 3, the voltage generator 400 may generate a first driving voltage ELVDD, a second driving voltage ELVSS, a first initialization voltage VINT1, a second initialization voltage VINT2, and a reset voltage VRST.

The display panel DP may include a display area DA corresponding to the transmission area TA (refer to FIG. 1) and a non-display area NDA corresponding to the bezel area BZA (refer to FIG. 1),

The display panel DP may include a plurality of pixels PX disposed in the display area DA and a plurality of sensors FA disposed in the display area DA. As an example, each of the sensors FX may be disposed between two pixels PX adjacent to each other. The pixels PX and the sensors FX may be alternately arranged with each other in the first and second directions DR1 and DR2. However, embodiments of the present disclosure are not necessarily limited thereto.

The display panel DP may include initialization scan lines SIL1 to SILn, compensation scan lines SCL1 to SCLn, write scan lines SWL1 to SWLn+1 light emission control lines EML1 to EMLn, the data lines DL1 to DLm, and the read-out lines RL1 to RLm. In an embodiment, the initialization scan lines SIL1 to SILn, the compensation scan lines SCL1 to SCLn, the write scan lines SWL1 to SWLn+1, and the light emission control lines EML1 to EMLn may extend in the second direction DR2. The initialization scan lines SIL1 to SILn, the compensation scan lines SCL1 to SCLn, the write scan lines SWL1 to SWLn+1, and the light emission control lines EML1 to EMLn may be arranged in the first direction DR1 and may be spaced apart from each other. The data lines DL1 to DLm and the read-out lines RL1 to RLm may extend in the first direction DR1 and may be arranged spaced apart from each other in the second direction DR2.

The pixels PX may be electrically connected to the initialization scan lines SIL1 to SILn, the compensation scan lines SCL1 to SCLn, the write scan lines SWL1 to SWLn+1, the light emission control lines EML1 to EMLn, and the data lines DL1 to DLm. Each of the pixels PX may be electrically connected to four scan lines. As an example, as shown in an embodiment of FIG. 3, pixels arranged in a first row may be connected to a first initialization scan line SIL1, a first compensation scan line SCL1, and first and second write scan lines SWL1 and SWL2. In addition, pixels arranged in a second row may be connected to a second initialization scan line SIL2, a second compensation scan line SCL2, and the second write scan line SWL2 and a third write scan line SWL3.

The sensors FX may be electrically connected to the initialization scan lines SIL1 to SILn, the compensation scan lines SCL1 to SCLn, and the read-out lines RL1 to RLm. Each of the sensors FX may be electrically connected to two scan lines. As an example, as shown in an embodiment of FIG. 3, sensors FX arranged in a first row may be connected to the first initialization scan line SIL1 and the first compensation scan line SCL1. In addition, sensors FX arranged in a second row may be connected to the second initialization scan line SIL2 and the second compensation scan line SCL2.

The scan driver 300 may be disposed in the non-display area NDA of the display panel DP. The scan driver 300 may receive the first control signal SCS from the driving controller 100. The first control signal SCS may include a start signal and a plurality of clock signals. Responsive to the first control signal SCS, the scan driver 300 may output initialization scan signals to the initialization scan lines SIL1 to SILn, may output compensation scan signals to the compensation scan lines SCL1 to SCLn, and may output write scan signals to the write scan lines SWL1 to SWLn+1.

The light emission driver 350 may be disposed in the non-display area NDA of the display panel DP. The light emission driver 350 may receive the second control signal ECS from the driving controller 100. The light emission driver 350 may output light emission control signals to the light emission control lines EML1 to EMLn in response to the second control signal ECS, According to an embodiment, alternatively, the scan driver 300 may be connected to the light emission control lines EML1 to EMLn. In this embodiment, the scan driver 300 may output the light emission control signals to the light emission control lines EML1 to EMLn.

The read-out circuit 500 may receive the fourth control signal RCS from the driving controller 100. The read-out circuit 500 may receive sensing signals from the read-out lines RL1-RLm in response to the fourth control signal RCS. The read-out circuit 500 may process the sensing signals from the read-out lines RL1-RLm and may provide the processed sensing signals S_FS to the driving controller 100. The driving controller 100 may recognize the biometric information based on the sensing signals S_FS.

Referring to an embodiment of FIG. 4, the display panel DP may include pixels PXR, PXG, and PXB and the sensors FX. The pixels PXR, PXG, and PXB may include light emitting elements ED_R, ED_G, and ED_B, respectively, and each of the pixels PXR, PXG, and PXB may include a pixel driving circuit PDC. Each of the sensors FX may include a light sensing element PE and a sensor driving circuit SDC.

The pixels PXR, PXG, and PSB and the sensors FX may be alternately arranged with each other in the first direction DR1 and in the second direction DR2. The pixels PXR, PXG, and PXB may include first pixels PXR including a light emitting element (hereinafter, referred to as a first light emitting element) ED_R emitting a light having a first color (e.g., a red color R), second pixels PXG including a light emitting element (hereinafter, referred to as a second light emitting element) ED_G emitting a light having a second color (e.g., a green color G), and third pixels PXB including a light emitting element (hereinafter, referred to as a third light emitting element) ED_B emitting a light having a third color (e.g., a blue color B). However, embodiments of the present disclosure are not necessarily limited thereto and the number of pixels and the respective colors thereof may vary.

The first pixels PXR may be alternately and repeatedly arranged with the third pixels PXB in the first and second directions DR1 and DR2. The second pixels PXG may be arranged in the first and second directions DR1 and DR2.

In an embodiment, each of the sensors FX may be disposed between the first pixel PXR and the third pixel PXB adjacent to first pixel PXR in the first and second directions DR1 and DR2. In addition, each of the sensors FX may be disposed between two second pixels PXG in the first and second directions DR1 and DR2. However, arrangements of the pixels PX and the sensors FX should not necessarily be limited thereto or thereby.

In the present embodiment, the first light emitting element ED_R may have a size greater than that of the second light emitting element ED_G. In addition, the third light emitting element ED_B may have a size that is greater than or equal to that of the first light emitting element ED_R. However, this is merely one example, and the size of each of the first, second, and third light emitting elements ED_R, ED_G, and ED_B should not necessarily be limited thereto or thereby. According to an embodiment, the first, second, and third light emitting elements ED_R, ED_G. and ED_B may have the same size as each other.

In addition, each of the first, second, and third light emitting elements ED_R, ED_G, and ED_B is shown as having a quadrangular shape, however, it should not necessarily be limited thereto or thereby. According to an embodiment, the shape of each of the first, second, and third light emitting elements ED_R, ED_G, and ED_B may have a variety of shapes, such as a polygonal shape, a circular shape, or an oval shape. In addition, the first, second, and third light emitting elements ED_R, ED_G, and ED_B may have different shapes from each other. For example, the second light emitting element ED_G may have a circular shape, and the first and third light emitting elements ED_R and ED_B may have a quadrangular shape.

The light sensing element PE may have a size less than that of the first and third light emitting elements ED_R and ED_B. As an example, the light sensing element PE may have a size that is less than or equal to that of the second light emitting element ED_G. However, the size of the light sensing element PE should not necessarily be limited thereto or thereby and may be changed in various ways. The light sensing element PE is shown as having a quadrangular shape, however, it should not necessarily be limited thereto or thereby. According to an embodiment, the light sensing element PE may have a variety of shapes, such as a polygonal shape, a circular shape, or an oval shape.

Each of the first, second, and third light emitting elements ED_R, ED_G, and ED_B may be electrically connected to a corresponding pixel driving circuit PDC. The pixel driving circuit PDC may include a plurality of transistors and a capacitor. The pixel driving circuits PDC respectively connected to the first, second, and third light emitting elements ED_R, ED_G, and ED_B may have the same circuit configurations.

The light sensing element PE may be electrically connected to a corresponding sensor driving circuit SDC. The sensor driving circuit SDC may include a plurality of transistors. As an example, the sensor driving circuit SDC and the pixel driving circuit PDC may be formed through the same process. In addition, the scan driver 300 may include transistors formed through the same processes as those applied to the pixel driving circuit PDC and the sensor driving circuit SDC.

The pixel driving circuit PDC may receive the first driving voltage ELVDD, the second driving voltage ELVSS, the first and second initialization voltages VINT1 and VINT2 from the voltage generator 400. The sensor driving circuit SDC may receive the first driving voltage ELVDD, the second driving voltage ELVSS, and the reset voltage VRST from the voltage generator 400. The pixel driving circuit PDC and the sensor driving circuit SDC will he described in detail below.

FIG. 5 is a circuit diagram of the pixel driving circuit PDC and the sensor driving circuit SDC according to an embodiment of the present disclosure. FIG. 5 shows an equivalent circuit diagram of one pixel PXij among the pixels PX shown in FIG. 3 as a representative example. The pixels PX may have the same circuit configuration, and thus, the circuit configuration of the pixel PXij will be described in detail, and details of the other pixels will be omitted. In addition, FIG. 5 shows an equivalent circuit diagram of one sensor FXij among the sensors FX shown in FIG. 3 as a representative example. The sensors FX may have the same circuit configuration, and thus, the circuit configuration of the sensor FXij will be described in detail, and details of the other sensors will be omitted for convenience of explanation.

Referring to an embodiment of FIG. 5, the pixel PXij may be connected to an i-th data line DLi (hereinafter, referred to as a data line) among the data lines DL1 to DLm, a j-th initialization scan line SILj (hereinafter, referred to as an initialization scan line) among the initialization scan lines SIL1 to SILn, a j-th compensation scan line SCLj (hereinafter, referred to as a compensation scan line) among the compensation scan lines SCL1 to SCLn, j-th and (j+1)th write scan lines SWLj and SWLj+1 (hereinafter, referred to as first and second write scan lines) among the write scan lines SWL1 to SWLn, and a j-th light emission control line EMLj (hereinafter, referred to as a light emission control line) among the light emission control lines EML1 to EMLn.

The pixel PXij may include the light emitting element ED and the pixel driving circuit PDC. The light emitting element ED may be a light emitting diode. As an example, the light emitting element ED may be an organic light emitting diode including an organic light emitting layer.

In an embodiment of FIG. 5, the pixel driving circuit PDC may include first, second, third, fourth, fifth, sixth, and seventh transistors T1, T2, T3, T4, T5, T6, and T7 and one capacitor Cst. In an embodiment, each of the first to seventh transistors T1 to T7 may be a transistor including a low-temperature polycrystalline silicon (LTPS) semiconductor layer. Some transistors of the first to seventh transistors T1 to T7 may be a P-type transistor, and the other transistors may be an N-type transistor. As an example, each of the first, second, fifth, sixth, and seventh transistors T1, T2, T5, T6, and T7 among the first to seventh transistors T1 to T7 may be a PMOS transistor, and each of the third and fourth transistors T3 and T4 may be an NMOS transistor including an oxide semiconductor as its semiconductor layer. According to an embodiment, at least one transistor of the first to seventh transistors T1 to T7 may be the N-type transistor, and the other transistors may be the P-type transistor. However, the configuration of the pixel driving circuit PDC should not necessarily be limited to the embodiment shown in FIG. 5. The pixel driving circuit PDC shown in FIG. 5 is merely one example, and the configuration of the pixel driving circuit PDC may be changed. As an example, all the first to seventh transistors T1 to T7 may be the P-type transistor or the N-type transistor.

The initialization scan line SILj, the compensation scan line SCLj, the first and second write scan lines SWLj and SWLj+1, and the light emission control line EMLj may transmit a j-th initialization scan signal GIj (hereinafter, referred to as an initialization scan signal), a j-th compensation scan signal GCj (hereinafter, referred to as a compensation scan signal), j-th and (j+1)th write scan signals GWj and GWj+1 (hereinafter, referred to as first and second write scan signals), and a j-th light emission control signal EMj (hereinafter, referred to as a light emission control signal) to the pixel PXij, respectively. The data line DLi may transmit a data signal Di to the pixel PXij. The data signal Di may have a voltage level corresponding to the image signal RGB input to electronic device EA (refer to FIG. 3).

First and second driving voltage lines NTL1 and VL2 may transmit the first driving voltage ELVDD and the second driving voltage ELVSS to the pixel PXij, respectively. In addition, first and second initialization voltage lines VL3 and VIA may transmit the first initialization voltage VINT1 and the second initialization voltage VINT2 to the pixel PXij, respectively.

The first transistor Ti may be connected between the first driving voltage line VL1 receiving the first driving voltage ELVDD and the light emitting element ED. The first transistor T1 may include a first electrode connected to the first driving voltage line VL1 via the fifth transistor T5, a second electrode electrically connected to an anode of the light emitting element ED via the sixth transistor T6, and a third electrode connected to one end of the capacitor Cst. The first transistor T1 may receive the data signal Di transmitted via the data line DLi according to a switching operation of the second transistor T2 and may supply a driving current to the light emitting element ED.

The second transistor T2 may be connected between the data line DLi and the first electrode of the first transistor T1. The second transistor T2 may include a first electrode connected to the data line DLi, a second electrode connected to the first electrode of the first transistor T1, and a third electrode connected to the first write scan line SWLj. The second transistor T2 may be turned on in response to the first write scan signal GWj applied thereto via the first write scan line SWLj and may transmit the data signal Di applied thereto via the data line DLi to the first electrode of the first transistor T1.

The third transistor T3 may be connected between the second electrode of the first transistor T1 and a first node N1. The third transistor T3 may include a first electrode connected to the third electrode of the first transistor T1, a second electrode connected to the second electrode of the first transistor T1, and a third electrode connected to the compensation scan line SCLj. The third transistor T3 may be turned on in response to the compensation scan signal GCj applied thereto via the compensation scan line SCLj and may connect the third electrode and the second electrode of the first transistor T1 to each other to allow the first transistor T1 to be connected in a diode configuration.

The fourth transistor T4 may be connected between the second initialization voltage line VL4 to which the second initialization voltage VINT2 is applied and the first node N1. The fourth transistor T4 may include a first electrode connected to the third electrode of the first transistor T1, a second electrode connected to the second initialization voltage line VL4 to which the second initialization voltage VINT2 is transmitted, and a third electrode connected to the initialization scan line SILj. The fourth transistor T4 may be turned on in response to the initialization scan signal GIj applied thereto via the initialization scan line SILj. The turned-on fourth transistor T4 may transmit the second initialization voltage VINT2 to the third electrode of the first transistor T1 to initialize an electric potential of the third electrode of the first transistor T1, e.g., an electric potential of the first node N1.

The fifth transistor T5 may include a first electrode connected to the first driving voltage line VL1, a second electrode connected to the first electrode of the first transistor T1, and a third electrode connected to the light emission control line EMLj. The fifth transistor T5 may be referred to as a first light emission control transistor.

The sixth transistor T6 may include a first electrode connected to the second electrode of the first transistor T1, a second electrode connected to the anode of the light emitting element ED, and a third electrode connected to the light emission control line EMLj. The sixth transistor T6 may be referred to as a second light emission control transistor.

The fifth transistor T5 and the sixth transistor T6 may be substantially simultaneously turned on in response to the light emission control signal EMj applied thereto via the light emission control line EMLj. The first driving voltage ELVDD applied via the turned-on fifth transistor T5 may be compensated for by the first transistor T1 connected in the diode configuration and may be transmitted to the light emitting element ED.

The seventh transistor T7 may include a first electrode connected to the first initialization voltage line VL3 to which the first initialization voltage VINT1. is transmitted, a second electrode connected to the second electrode of the sixth transistor T6, and a third electrode connected to the second write scan line SWLj+1. In an embodiment, the first initialization voltage VINT1 may have a voltage level lower than or equal to that of the second initialization voltage VTNT2.

As described above, the one end of the capacitor Cst may be connected to the third electrode of the first transistor T1, and the other end of the capacitor Cst may be connected to the first driving voltage line VL1. A cathode of the light emitting element ED may be connected to the second driving voltage line VL2 that transmits the second driving voltage ELVSS. The second driving voltage ELVSS may have a voltage level lower than that of the first driving voltage ELVDD. As an example, the second driving voltage ELVSS may have a voltage level lower than that of the first and second initialization voltages VINT1 and VINT2.

When the initialization scan signal GIj at high level is provided via the initialization scan line SILj, the fourth transistor T4 may be turned on in response to the initialization scan signal GIj at the high level, The second initialization voltage VIINT2 may be applied to the third electrode of the first transistor T1 via the turned-on fourth transistor T4, and the first node N1 may be initialized by the second initialization voltage VINT2. Accordingly, a high level period of the initialization scan signal GIj may be an initialization period of the pixel PXij.

Then, when the compensation scan signal GCj at high level is provided via the compensation scan line SC1Lj, the third transistor T3 may be turned on. The first transistor T1 may be connected in a diode configuration and may be forward biased by the turned-on third transistor T3. In addition, the second transistor T2 may be turned on in response to the first write scan signal GWj at low level. Then, a compensation voltage obtained by subtracting a threshold voltage Vth of the first transistor T1 from the data signal Di provided via the data line DLi may be applied to the third electrode of the first transistor T1.

The first driving voltage ELVDD and the compensation voltage Di-Vth may be respectively applied to both ends of the capacitor Cst, and the capacitor Cst may be charged with electric charges corresponding to a difference in voltage between the both ends of the capacitor Cst.

The seventh transistor T7 may be turned on in response to the second write scan signal GWj+1 having the low level applied thereto via the second write scan line SWLj+1. A portion of the driving current Id may be bypassed as a bypass current via the seventh transistor T7.

When the light emitting element ED emits a light even though a minimum current of the first transistor T1 displaying a black image flows as the driving current, the pixel PXij may not properly display the black image. Therefore, the seventh transistor T7 of the pixel PXij according to an embodiment of the present disclosure may bypass a portion of the minimum current of the first transistor T1 to another current path as a bypass current Ibp rather than to a current path to the light emitting element ED. In this embodiment, the minimum current of the first transistor T1 means a current flowing to the first transistor T1 under a condition that a gate-source voltage of the first transistor Ti is less than the threshold voltage Vth and the first transistor T1 is turned off. In this way, when the minimum current that turns off the first transistor T1 is transmitted to the light emitting element ED, an image with a black grayscale may be displayed. In an instance in which the minimum current used to display the black image flows, an influence of bypass transmission of the bypass current is relatively large, however, in an instance in which a high driving current used to display images, such as a normal image or a white image, flows, the influence of the bypass current may be negligible, Accordingly, when the driving current used to display the black image flows, a light emitting current of the light emitting element ED having a voltage obtained by subtracting an amount of the bypass current, which is bypassed through the seventh transistor T7, from the driving current Id may have a minimum amount of current at a level appropriate to clearly display the black image. Thus, the pixel PXij may display an accurate black luminance image using the seventh transistor T7, and as a result, a contrast ratio may be increased.

Then, a level of the light emission control signal EMj provided from the light emission control line EMLj may be changed to a low level from a high level. The fifth transistor T5 and the sixth transistor T6 may be turned on in response to the light emission signal EMj having the low level. As a result, the driving current may be generated due to a difference in voltage between the voltage of the third electrode of the first transistor T1 and the first driving voltage ELVDD, the driving current may be supplied to the light emitting element ED via the sixth transistor T6, and thus, the light emitting current may flow through the light emitting element ED.

The sensor FXij may be connected to an i-th read-out line RLi (hereinafter, referred to as a read-out line) among the read-out lines RL1 to Rtm, a (j−1)th write scan signal line SWLj−1, and a j-th signal line SLj (hereinafter, referred to as a signal line). In addition, the sensor FXij may be connected to first, second, and third sensing driving voltage lines VL5, VL6, and VL7.

The sensor FXij may include the light sensing element PE and the sensor driving circuit SDC. The light sensing element PE may include a photodiode. As an example, the light sensing element PE may include the photodiode containing an inorganic material as its photoelectric conversion layer. An anode of the light sensing element PE may be connected to a first sensing node SN1, and a cathode of the light sensing element PE may be connected to the third sensing driving voltage line VL7. The third sensing driving voltage line VL7 may provide a bias voltage Vbias.

In an embodiment of FIG. 5, the sensor driving circuit SDC may include three transistors ST1, ST2, and ST3. The three transistors ST1, ST2, and ST3 may be an amplification transistor ST1, an output transistor ST2, and a reset transistor ST3. Some of the amplification transistor ST1, the output transistor ST2, and the reset, transistor ST3 may be a P-type transistor, and the other may be an N-type transistor. As an example, each of the amplification transistor ST1 and the output transistor ST2 may be a PMOS transistor, and the reset transistor ST3 may be an NMOS transistor. However, embodiments of the present disclosure should not necessarily be limited thereto or thereby, and all the amplification transistor ST1, the output transistor ST2, and the reset transistor ST3 may be the N-type transistor or the P-type transistor.

The circuit configuration of the sensor driving circuit SDC should not necessarily be limited to an embodiment shown in FIG. 5. The sensor driving circuit SDC shown in FIG. 5 is merely an example, and the circuit configuration of the sensor driving circuit SDC may be changed.

The amplification transistor ST1 may include a first electrode connected to the first sensing driving voltage line VL5, a second electrode connected to the output transistor ST2, and a third electrode connected to the first sensing node SN1. The first sensing driving voltage line VL5 may provide various voltages. As an example, the first sensing driving voltage line VL5 may provide a gate low voltage, a initialization voltage, or the first driving voltage ELVDD. In an embodiment of FIG. 5, the first sensing driving voltage line VL5 is shown as providing the first driving voltage ELVDD, The amplification transistor ST1 may be turned on in response to an electric potential of the first sensing node SNI and may apply the first driving voltage ELVDD to the output transistor ST2.

In an embodiment in which the first sensing driving voltage line VL5 provides the first driving voltage ELVDD, the first sensing driving voltage line VL5 may be provided integrally with the first driving voltage line VL1, however, it should not necessarily be limited thereto or thereby. According to an embodiment, the first sensing driving voltage line VL5 may be formed independently from the first driving voltage line VL1, and it should not necessarily be particularly limited thereto.

The output transistor ST2 may include a first electrode connected to the amplification transistor ST1, a second electrode connected to the read-out line RLi, and a third electrode connected to the (j−1)th write scan line SWLj−1 receiving the (j-1)th —rite scan signal GWj−1. The output transistor ST2 may transmit a sensing signal VRi to the read-out line RLi in response to the (j−1)th write scan signal GWj−1.

The reset transistor ST3 may include a first electrode connected to the second sensing driving voltage line VL6 receiving the reset voltage VRST, a second electrode connected to the first sensing node SN1, and a third electrode connected to the signal line SLj receiving a reset signal Reset. The reset transistor ST3 may reset an electric potential of the first sensing node SN1 to the reset voltage VRST in response to the reset signal Reset. As an example, the reset voltage VRST may have a voltage level lower than that of the second driving voltage ELVSS. As an example, the reset voltage VRST may be the gate low voltage VGL, however, this is merely an example. According to an embodiment, the reset voltage VRST should not necessarily be particularly limited thereto as long as the reset voltage VRST may rest the first sensing node SN1. In an embodiment, the reset transistor ST3 may include a plurality of sub-reset transistors connected in series between the second sensing driving voltage line VL6 and the first sensing node SN1.

In an embodiment of FIG. 5, the signal line SLj that turns on the reset transistor ST3 may be provided independently from the scan lines connected to the pixel driving circuit PDC, e.g. the write scan line, the compensation scan line, and the initialization scan line, however, this is merely one example. According to an embodiment, the signal line SLj may be provided using some of the scan lines, and the reset signal Reset may be one of the scan signals, and they should not necessarily be particularly limited thereto.

The light sensing element PE may receive a light emitted from the light emitting element ED of the pixel PXij and reflected by the user's hand to sense fingerprint information. For example, when the user's hand US_F (refer to FIG. 1) touches the front surface IS (refer to FIG. 1), the light sensing element PE may generate photo-charges corresponding to the light reflected by ridges of the user's fingerprint or valleys between the ridges of the user's fingerprint, and the generated photo-charges may be accumulated in the first sensing node SN1.

The amplification transistor ST1 may be a source follower amplifier that generates a source-drain current in proportion to an amount of charge of the first sensing node SN1 input to the third electrode.

As described above, the display panel DP may include the pixel PXij and the sensor FXij, and the sensor FXij may be operated through the signal line formed in the display panel DP. Accordingly, a process of assembling the sensor using an adhesive layer may be omitted. In addition, the user's biometric information may be sensed while displaying the image at the same time as displaying the image through one display panel, and thus, the user's convenience of the electronic device may be increased.

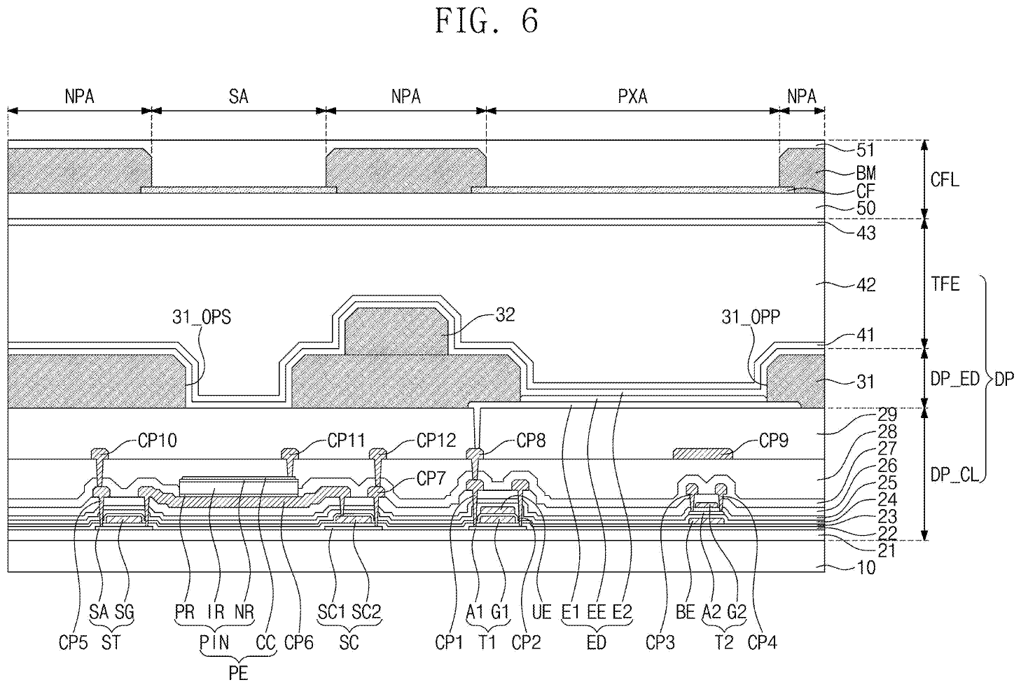

FIG. 6 is a cross-sectional view of an electronic device according to an embodiment of the present disclosure.

Referring to FIG. 6, the electronic device EA may include a base layer 10, a display panel DP, and a color filter layer CFL. The base layer 10 may correspond to the base layer BL shown in FIG. 2.

In an embodiment, the base layer 10 may include a synthetic resin layer. The synthetic resin layer may include a heat-curable resin. The synthetic resin layer may include a polyimide-based resin, however, a material for the synthetic resin layer should not necessarily be particularly limited thereto. The synthetic resin layer may include at least one material selected from an acrylic-based resin, a methacrylic-based resin, a polyisoprene-based resin, a vinyl-based resin, an epoxy-based resin, a urethane-based resin, a cellulose-based resin, a siloxane-based resin, a polyamide-based resin, and a perylene-based resin. According to an embodiment, the base layer 10 may include a glass substrate, a metal substrate, or an organic/inorganic composite substrate.

A circuit layer DP_CL may be disposed on the base layer 10 (e.g., directly thereon in the third direction DR3). The circuit layer DP_CL may include a plurality of insulating layers 21, 22, 23, 24, 25, 26, 27, 28, and 29, a plurality of driving elements ST, SC, T1, and T2, and a light sensing element PE. For example, in an embodiment, the insulating layers 21, 22, 23, 24, 25, 26, 27, 28, and 29 may include first, second, third, fourth, fifth, sixth, seventh, eighth, and ninth insulating layers 21, 22, 23, 24, 25, 26, 2.7, 28, and 29, and the driving elements ST, SC, T1, and T2 may include a sensing transistor ST, a sensing capacitor SC, a first pixel transistor T1, and a second pixel transistor T2.

In an embodiment, the first insulating layer 21 may include an inorganic layer. The inorganic layer may include at least one compound selected from aluminum oxide, titanium oxide, silicon oxide, silicon oxynitride, zirconium oxide, and hafnium oxide. The inorganic layer may include a plurality of layers. The inorganic layers may form a barrier layer and/or a buffer layer. The barrier layer and the buffer layer may be selectively disposed.

The barrier layer may prevent a foreign substance from entering from the outside. In an embodiment, the barrier layer may include a silicon oxide layer and a silicon nitride layer. Each of the silicon oxide layer and the silicon nitride layer may be provided in plural, and the silicon oxide layers and the silicon nitride layers may be alternately stacked with each other.

The buffer layer may be disposed on the barrier layer. The buffer layer may increase a coupling force between the base layer 10 and a semiconductor pattern and/or a conductive pattern. in an embodiment, the buffer layer may include a silicon oxide layer and a silicon nitride layer. The silicon oxide layer and the silicon nitride layer may be alternately stacked with each other.

The first pixel transistor T1 may correspond to the first transistor T1 shown in an embodiment of FIG. 5. The first pixel transistor T1 may include a first control electrode G1 and a first semiconductor pattern A1. The first semiconductor pattern A1 may be disposed between the first insulating layer 21 and the second insulating layer 22, and the first control electrode G1 may be disposed between the second insulating layer 22 and the third insulating layer 23.

The first semiconductor pattern A1 may include a semiconductor material. As an example, the first semiconductor pattern A1 may include polysilicon, however, it should not necessarily be limited thereto or thereby. According to an embodiment, the first semiconductor pattern A1 may include amorphous silicon, crystalline silicon, or oxide semiconductor.

In the present embodiment, the first semiconductor pattern A1 may include a channel, a source, and a drain. The channel may be formed in an area overlapping the first control electrode G1 in the first semiconductor pattern A1 when viewed in a plane. The source and the drain may be spaced apart from each other with the channel interposed therebetween. The source and the drain may have a relatively high conductivity compared to the channel. As an example, the source and the drain may be doped regions of the first semiconductor pattern A1. A P-type transistor may include a doped region doped with a P-type dopant, and an N-type transistor may include a doped region doped with an N-type dopant.

The source and the drain may respectively correspond to the first electrode and the second electrode of the first transistor T1 shown in an embodiment of FIG. 5, however, this is merely one example. According to an embodiment, the source and the drain of the first pixel transistor T1 may be provided as electrodes that are in contact with the first semiconductor pattern A1, and they should not necessarily be particularly limited thereto.

The first control electrode G1 may be disposed on the third insulating layer 23 and may overlap the first semiconductor pattern A1 in a plane (e.g., in the third direction DR3). The first control electrode G1 may be a portion of a metal pattern. The first control electrode G1 may serve as a mask in a process of doping the first semiconductor pattern A1. The first control electrode G1 may correspond to the third electrode of the first transistor T1 shown in an embodiment of FIG. 5.

Each of the second and third insulating layers 22 and 23 may include an inorganic layer and/or an organic layer and may have a single-layer or multi-layer structure. in an embodiment, the inorganic layer may include at least one compound selected form aluminum oxide, titanium oxide, silicon oxide, silicon oxynitride, zirconium oxide, and hafnium oxide. Each of the insulating layers described below may be an inorganic layer and/or an organic layer and may have a single-layer or multi-layer structure. The inorganic layer may include at least one of the above-mentioned materials.

In an eirtbodiment, the electronic device EA may further include an upper electrode UE disposed on the first control electrode G1. The upper electrode UE may be disposed between the third insulating layer 23 and the fourth insulating layer 24. The upper electrode UE may be a portion of the metal pattern.

The upper electrode UE may be disposed to be spaced apart from the first control electrode G1 with the third insulating layer 23 interposed therebetween. The upper electrode LE and the first control electrode G1 may form a capacitor. The capacitor may correspond to the capacitor Cst shown in an embodiment of FIG. 5 or may be a portion of the capacitor Cst. Accordingly, an area of the pixel driving circuit PDC may be prevented from increasing due to the capacitor Cst, and thus, it is advantageouso design a high-resolution circuit. However, this is merely one example, and the upper electrode UE may be omitted.

The second pixel transistor T2 may include a second semiconductor pattern A2 and a second control electrode G2. The second semiconductor pattern A2 may be disposed between the fourth insulating layer 24 and the fifth insulating layer 25, and the second control electrode G2 may be disposed between the fourth insulating layer 24 and the fifth insulating layer 25. The third insulating layer 23 may cover the first pixel transistor T1. Accordingly, the second pixel transistor T2 may be formed after the first pixel transistor T1 is formed.

The second semiconductor pattern A2 may be disposed on a layer different from a layer on which the first semiconductor pattern A1 is disposed. The second semiconductor pattern A2 may include a matetial different from that of the first semiconductor pattern A1. As an example, in an embodiment, the second semiconductor pattern A2 may include an oxide semiconductor, however, this is merely one example. According to an embodiment, the first semiconductor pattern A1 may include polysilicon, amorphous silicon, or crystalline silicon, and it should not necessarily be particularly limited thereto. In addition, the second semiconductor pattern A2 may be disposed on the same layer as a layer on which the first semiconductor pattern A1 is disposed, however, it should not necessarily be particularly limited thereto.

The second semiconductor pattern A2 may include a channel overlapping the second control electrode G2 a source, and a drain spaced apart from the source with the channel interposed therebetween. The source and the drain may respectively correspond to the first electrode and the second electrode of the second transistor T2 shown in an embodiment of FIG. 5, and the second control electrode G2 may correspond to the third electrode of the second transistor T2 shown in an embodiment of FIG. 5. Detailed descriptions of the second semiconductor pattern A2 and the second control electrode G2 correspond to the detailed descriptions of the first semiconductor pattern A1 and the first control electrode G1, and thus, detailed descriptions thereof will be omitted for convenience of explanation.

In an embodiment, the electronic device EA may further include a lower electrode BE disposed under the second semiconductor pattern A2 to overlap the second control electrode G2. The lower electrode BE may be disposed on the same layer as a layer on which the upper electrode UE is disposed. The lower electrode BE may be a portion of a metal pattern.

The lower electrode BE may prevent the second semiconductor pattern A2 from being damaged due to a light provided from the base layer 10. In addition, the lower electrode BE may receive an electrical signal and may allow the second transistor T2 to have a double-gate structure, however, this is merely o example. According to an embodiment, the lower electrode BE may be omitted from the electronic device EA.

The sensing transistor ST may include a semiconductor pattern SA and a control electrode SG. The semiconductor pattern SA may be disposed on the same layer as a layer on which the first semiconductor pattern A1 is disposed. In an embodiment, the semiconductor pattern SA may be substantially simultaneously formed with the first semiconductor pattern A1 through the same process using the same material, however, this is merely one example. According to an embodiment, the semiconductor pattern SA may be disposed on a layer different from the layer on which the first semiconductor pattern A1 is disposed or may be formed of a material different from a material of the first semiconductor pattern A1.

The semiconductor pattern SA may include a channel overlapping the control electrode SG, a source, and a drain spaced apart from the source with the channel interposed therebetween. In an embodiment, the source and the drain may respectively correspond to the first electrode and the second electrode of the reset transistor ST3 shown in an embodiment of FIG. 5, and the control electrode SG may correspond to the third electrode of the reset transistor ST3 shown in an embodiment of FIG. 5. Detailed descriptions of the semiconductor pattern SA and the control electrode SG correspond to the detailed descriptions of the first semiconductor pattern A1 and the first control electrode G1, and thus, detailed descriptions thereof will be omitted for convenience of explanation.

The sensing capacitor SC may include a first capacitor electrode SC1 and a second capacitor electrode SC2. The first capacitor electrode SC1 and the second capacitor electrode SC2 may be disposed to be spaced apart from each other with the second insulating layer 22 interposed therebetween.

The first capacitor electrode SC1 may be disposed on the same layer as the layer on which the first semiconductor pattern A1 is disposed. The first capacitor electrode SC1 may be formed of the same semiconductor material as that of the first semiconductor pattern A1, and an entire area of the first capacitor electrode SC1 is provided as a doped region such that the first capacitor electrode SC1 may have a conductivity. The second capacitor electrode SC2 may he disposed on the same layer as a layer on which the first control electrode G1 is disposed. The second capacitor electrode SC2 may include a metal material, however, this is merely one example. According to an embodiment, the first capacitor electrode SC1 and the second capacitor electrode SC2 may be disposed on the layers different from the layers on which the first semiconductor pattern A1 and the first control electrode G1 are disposed or may be formed of a material different from a material of the first semiconductor pattern A1 and the first control electrode G1, however, they should not necessarily be particularly limited thereto.

The sixth insulating layer 26 may be disposed on the fifth insulating layer 25 to cover the second pixel transistor T2. A plurality of conductive patterns CP1, CP2, CP3, CP4, CP5, CP6, and CP7 may be disposed on the sixth insulating layer 26. The conductive patterns CP1, CP2, CP3, CP4, CP5, CP6, and CP7 may be covered by the seventh insulating layer 27. The driving elements may be electrically connected to each other by the conductive patterns CP1, CP2, CP3, CP4, CP5, CP6, and CP7. In an embodiment, the conductive patterns CP1, CP2, CP3, CP4, CP5, CP6, and CP7 may include first, second, third, fourth, fifth, sixth, and seventh conductive patterns CP1, CP2, CP3. CP4, CP5, CP6, and CP7.

The first conductive pattern CP1 and the second conductive pattern CP2 may he connected to the first pixel transistor T1. For example, the first conductive pattern CP1. may be connected to the drain of the first pixel transistor T1 (e.g., the second electrode of the first transistor and the second conductive pattern CP2 may be connected to the source of the first pixel transistor T1 (e.g., the first electrode of the first transistor).

The third conductive pattern CP3 and the fourth conductive pattern CP4 may he connected to the second pixel transistor T2. For example, the third conductive pattern CP3 may be connected to the source of the second pixel transistor T2 (e.g., the first electrode of the second transistor), and the fourth conductive pattern CP4 may be connected to the source of the second pixel transistor T2 (e.g., the second electrode of the second transistor).

The fifth conductive pattern CP5 and the sixth conductive pattern CP6 may be connected to the sensing transistor ST. The fifth conductive pattern CP5 may be connected to the source of the sensing transistor ST (e.g., the first electrode of the reset transistor), and the sixth conductive pattern CP6 may be connected to the drain of the sensing transistor ST (e.g., the second electrode of the reset transistor).

The sixth conductive pattern CP6 may be connected to the sensing capacitor SC. The sixth conductive pattern CP6 and the seventh conductive pattern CP7 may be respectively connected to the second capacitor electrode SC2 and the first capacitor electrode SC1.

The light sensing element PE may be disposed on the sixth conductive pattern CP6 (e.g., disposed directly thereon in the third direction DR3). Therefore, the light sensing element PE may be disposed on a higher layer than layers that the first transistor T1 and the second transistor T2 are disposed thereon. In an embodiment, the light sensing element PE may include a photodiode PIN and a cathode CC. The photodiode PIN may be in direct contact with the sixth conductive pattern CP6 after penetrating through the seventh insulating layer 27. In an embodiment, the sixth conductive pattern CP6 may correspond to the anode of the light sensing element PE, however, this is merely one example. According to an embodiment, a separate conductive pattern that serves as the anode may be disposed between the sixth conductive pattern CP6 and the photodiode PIN, and it should not necessarily be particularly limited thereto.

The seventh insulating layer 27 may have a single-layer structure of a silicon oxide layer, however, this is merely one example. As described above, the seventh insulating layer 27 may include an inorganic layer and/or an organic layer and may have a single-layer or multi-layer structure. In addition, the inorganic layer may include at least one of the above-mentioned inorganic materials.

The photodiode PIN may include a silicon-based diode and may include structures with various junction types. As an example, the photodiode PIN may include a PN type diode, a PIN type diode, a Schottky diode, or an avalanche diode. In an embodiment of FIG. 6, the PIN type diode is shown as a representative example.

In an embodiment, the photodiode PIN may include a P-type region PR, an intrinsic region IR, and an N-type region NR, which are sequentially stacked (e.g., in the third direction DR3). Each of the P-type region PR, the intrinsic region IR, and the N-type region NR may include a semiconductor material. As an example, the P-type region PR may include a P-type amorphous silicon, the intrinsic region IR may include an I-type amorphous silicon, and the N-type region NR may include an N-type amorphous silicon. However, embodiments of the present disclosure are not necessarily limited thereto.

The cathode CC may be disposed on the photodiode PIN e.g., directly thereon in the third direction DR3). In an embodiment, the cathode CC may be in direct contact with the N-type region NR. The cathode CC may have a conductivity. As an example, the cathode CC may be a conductive pattern, such as an electrode that includes a transparent conductive oxide. Accordingly, the light reflected by the user's fingerprint, which is provided on the front surface IS (refer to FIG. 1), may stably reach the photodiode PIN after passing through the cathode CC, however, this is merely one example. According to an embodiment, the cathode CC may include a metal or metal oxide and may be provided to overlap a portion of the photodiode PIN, and it should not necessarily be particularly limited thereto.

The eighth insulating layer 28 may cover the light sensing element PE. A plurality of conductive patterns CP8, CP9, CP10, CP11, and CP12 may be disposed on the eighth insulating layer 28. The conductive patterns CP8, CP9, CP10, CP11, and CP12 may include eighth, ninth, tenth, eleventh, and twelfth conductive patterns CPS, CP9, CP10, CP11, and CP12.

The eighth conductive pattern CPS may be connected to the first pixel transistor T1 after penetrating through the eighth insulating layer 28. The ninth conductive pattern CP9 may be a portion of the conductive patterns that connect the driving elements of the pixel driving circuit PDC. In addition, the ninth conductive pattern CP9 may block a light traveling thereto from an upper side thereof from reaching the second pixel transistor T2.

The tenth conductive pattern CP1.0 may be connected to the sensing transistor ST. The tenth conductive pattern CP10 may apply an electrical signal to the sensing transistor ST through the fifth conductive pattern CP5, As an example, the tenth conductive pattern CP10 may correspond to the second sensing driving voltage line VL6 (refer to FIG. 5) that transmits the reset voltage RST (refer to FIG. 5).

The eleventh conductive pattern CP11 may be connected to the light sensing element PE. The eleventh conductive pattern CP11 may be connected to the cathode CC after penetrating through the eighth insulating layer 28. Accordingly, the eleventh conductive pattern CP11 may correspond to the third sensing driving voltage line VL7 (refer to FIG. 5). The light sensing element PE may receive the bias voltage through the eleventh conductive pattern CP11, however, this is merely one example. According to an embodiment, the eleventh conductive pattern CP11 may receive a variety of voltages, and it should not necessarily be particularly limited thereto.

The twelfth conductive pattern CP12 may be connected to the sensing capacitor SC. The twelfth conductive pattern CP12. may be connected to the seventh conductive pattern Cp7 connected to the first capacitor electrode SC1 after penetrating through the eighth insulating layer 28. The twelfth conductive pattern. CP12 may receive the bias voltage, however, this is merely one example. According to an embodiment, the twelfth conductive pattern CP12 may receive a common voltage or various other voltages, and it should not necessarily be particularly limited thereto.

The ninth insulating layer 29 may be disposed on the eighth insulating layer 28 and may cover the conductive patterns CP8, CP9, CP10, CP11, and CP12. Each of the eighth insulating layer 28 and the ninth insulating layer 29 may have a single-layer structure of a polyimide-based resin layer, however, this is merely one example. According to an embodiment, each of the eighth insulating layer 28 and the ninth insulating layer 29 may include an organic layer and/or an inorganic layer and may have a single-layer or multi-layer structure. The organic layer may include at least one material selected from an acrylic-based resin, a methacrylic-based resin, a polyisoprene-based resin, a vinyl-based resin, an epoxy-based resin, a urethane-based resin, a cellulose-based resin, a siloxane-based resin, a polyamide-based resin, and a perylene-based resin. The inorganic layer may include at least one of the above-mentioned inorganic materials.

An element layer DP_ED may be disposed on the circuit layer DP_CL (e.g., in the third direction DR3). The element layer DP_ED may include an light emitting element ED, a pixel definition layer 31, and a spacer 32. The light emitting element ED may include a first electrode e1, a light emitting layer EE, and a second electrode E2. The first electrode E1 of the light emitting element ED may be disposed on the ninth insulating layer 29 (e.g., disposed directly thereon in the third direction DR3). The first electrode E1 of the light emitting element ED may be anode of the light emitting element and the second electrode E2 may be cathode of the light emitting element in this embodiment. The first electrode E1 of the light emitting element ED may be connected to the eighth conductive pattern CP8 after penetrating through the ninth insulating layer 29.

The pixel definition layer 31 may include a first opening 31_OPP and a second opening 31_OPS. The first opening 31_OPP and the second opening 31_OPS may be defined through the pixel definition layer 31. For example, the first opening 31_OPP and the second opening 31_OPS may extend completely through the pixel definition layer 31 (e.g., in the third direction DR3).

The first opening 31_OPP may overlap a light emitting area PXA and a light emitting element ED. The first opening 31_OPP may define an area where the light is emitted from the light emitting element ED. At least a portion of the first electrode E1 of the light emitting element ED may be exposed through the first opening 31_OPP.

The second opening 31_OPS may overlap a sensing area SA and a light sensing element PE. The second opening 31_OPS may define an area where the light reflected by the user's fingerprint, which is provided to the front surface IS, is incident into the light sensing element The light sensing element PE may receive the light passing through the second opening 31_OPS to sense the fingerprint information.

In an embodiment, the pixel definition layer 31 may have a black color. The pixel definition layer 31 nay further include a separate black material. As an example, the pixel definition layer 31 may further include a black organic dye/pigment, such as a carbon black or an aniline black. In an embodiment, the pixel definition layer 31 may be formed by mixing a blue organic material with a black organic material. The pixel definition layer 31 may further include a liquid-repellent organic material, however, this is merely one example. According to an embodiment, the dye/pigment of the pixel definition layer 31 may be omitted.

The spacer 32 may be disposed on the pixel definition layer 31 (e.g., directly thereon in the third direction DR3), In an embodiment, the spacer 32 may be disposed on a portion of the pixel definition layer 31. The spacer 32 may support a mask used in a process of forming the light emitting layer EE and may prevent the mask from being damaged. In an embodiment, the spacer 32 may be formed of the same material as that of the pixel definition layer 31, however, this is merely one example. According to an embodiment, the spacer 32 may be formed of a material different from a material used to form the pixel definition layer 31. In addition, the spacer 32 may be formed integrally with the pixel definition layer 31, however, it should not necessarily be particularly limited thereto.

The light emitting layer EE may be disposed on the first opening 31_OPP, In an embodiment, the light emitting layer EE may be disposed only in an area overlapping the opening 31_OPP. The light emitting layer EE may be formed in each of the pixels PX after being patterned. The light emitting layer EE may be formed on a higher layer than the layer that the light sensing element PE is formed thereon. Therefore, the light sensing element PE. may be disposed between a layer on which the first transistor T1 and the second transistor T2 are disposed and a layer on which the light emitting element EE is disposed.

In an embodiment of FIG. 6, the patterned light emitting layer EE is shown as a representative example, however, the light emitting layer EE may be commonly disposed in the pixels PX, In an embodiment, the light emitting layer EE may generate a white light or a blue light. In addition, the light emitting layer EE may have a multi-layer structure.

The second electrode E2 may be disposed on the light emitting layer EE. In an embodiment, the second electrode E2 may be commonly disposed in the pixels PX. An encapsulation layer TFE may be disposed on the second electrode E2. The encapsulation layer TFE may cover the pixels PX. In an embodiment, the encapsulation layer TFE may directly cover the second electrode E2 of the light emitting element ED.

In an embodiment, the encapsulation layer TFE may include a first layer 41, a second layer 42, and a third layer 43. Each of the first layer 41, the second layer 42, and the third layer 43 may be an inorganic layer or an organic layer. As an example, in an embodiment, the first layer 41, the second layer 42, and the third layer 43 may be the inorganic layer, the organic layer, and the inorganic layer, respectively. The encapsulation layer TFE may include a plurality of inorganic layers and a plurality of organic layers alternately stacked with the inorganic layers.

The inorganic layer of the encapsulation layer TFE may protect the light emitting element ED from moisture and oxygen, and the organic layer of the encapsulation layer TFE may protect the light emitting element ED from a foreign substance such as dust particles. The inorganic layer may include a silicon nitride layer, a silicon oxynitride layer, a silicon oxide layer, a titanium oxide layer, or an aluminum oxide layer, however, it should not necessarily be limited thereto or thereby. The organic layer may include an acrylic-based organic layer, however, it should not necessarily be particularly limited thereto.

The color filter layer CFL may be disposed on the encapsulation layer TFE (e.g., directly thereon in the third direction DR3). The color filter layer CFL may include a plurality of insulating layers 50 and 51, a black matrix BM, and a color filter CF. The insulating layers 50 and 51 may include a first protective layer 50 and a second protective layer 51. The black matrix BM may substantially define a non-light-emitting area NPA. The black matrix BM may include openings extending therethrough that overlap the first and second openings 31_OPP, 31_OPS. The black matrix BM may block a light incident thereto to prevent the light from being incident into other areas other than the light emitting area PXA or the sensing area SA. Accordingly, a detect in which a lower driving element is viewed due to the external light may be prevented, and thus, a visibility of the electronic device may be increased.

The color filter CF and the black matrix BM may be disposed between the first protective layer 50 and the second protective layer 51. Each of the first protective layer 50 and the second protective layer 51 may be an organic material and/or an inorganic material. However, embodiments of the present disclosure are not necessarily limited thereto. For example, in an embodiment, one of the first protective layer 50 and the second protective layer 51 may be omitted in the electronic device.

According to an embodiment, the sensing area SA in which the fingerprint is sensed and the light emitting area PXA in which the image is displayed may be implemented in one display panel DP. In addition, since the light sensing element PE may be provided in the circuit layer CP_CL, it is possible to sense the fingerprint while the image is being displayed through a single panel.

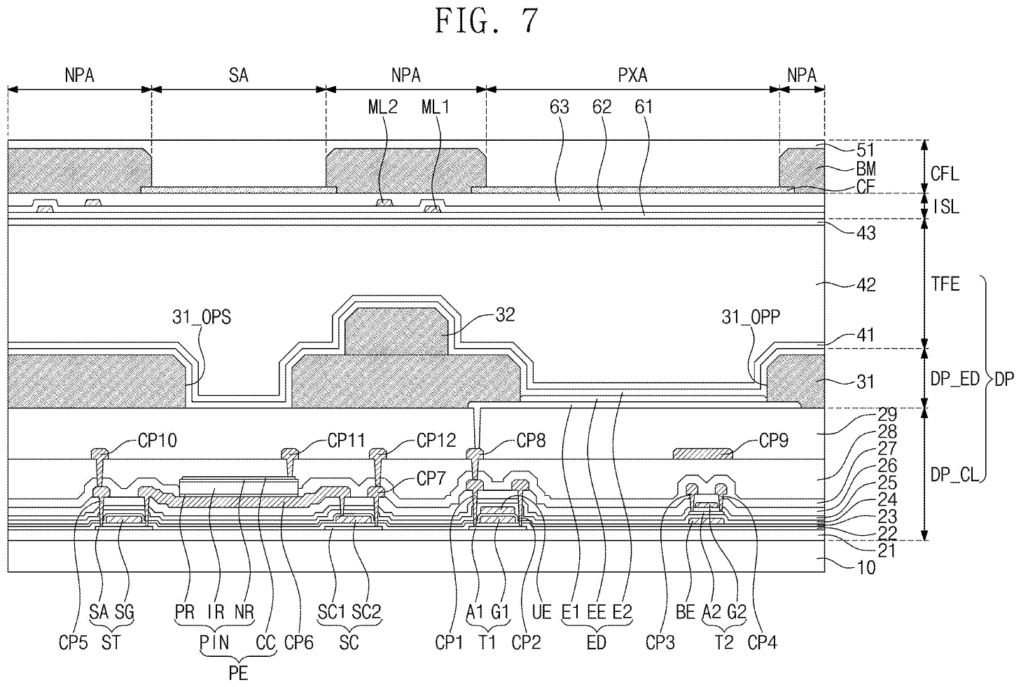

FIG. 7 is a cross-sectional view of an electronic device according to an embodiment of the present disclosure. For the convenience of explanation, FIG. 7 shows the electronic device in an area corresponding to the area of the electronic device shown in FIG. 6. In FIG. 7, the same reference numerals denote the same elements in FIG. 6, and thus, detailed descriptions of the same elements may be omitted for convenience of explanation.

Referring to an embodiment of FIG. 7, the electronic device EA may further include an input sensing layer ISL. The input sensing layer ISL may be disposed between a display panel DP and a color filter layer CFL (e.g., in the third direction DR3), however, this is merely one example. According to an embodiment, a position of the input sensing layer ISL may be designed in various ways and should not necessarily be particularly limited thereto.

The input sensing layer ISL may include a plurality of insulating layers 61, 62, and 63 and conductive layers ML1 and ML2. The conductive layers ML1 and ML2 may be disposed on different layers from each other. in an embodiment, each of the conductive layers ML1 and ML2 may include mesh lines. The mesh lines may be disposed to overlap a non-light-emitting area NPA. For example, the mesh lines may be disposed to overlap the pixel definition layer 31 when viewed in a plane((e.g., a plane viewed from the third direction DR3). Accordingly, in a light emitting area PXA. or a sensing area SA, the mesh lines may be prevented from being viewed. However, this is merely one example, and each of the conductive layers ML1 and ML2 may include a transparent conductive oxide and may be disposed to overlap the light emitting area PXA or the sensing area SA, and it should not necessarily be particularly limited thereto.

According to an embodiment of FIG. 7, it is possible to detect a touch event applied from the outside or to sense the user's biometric information while the image is being displayed through a single panel. Accordingly, the electronic device with various functions may be provided, and the user's convenience may be increased.

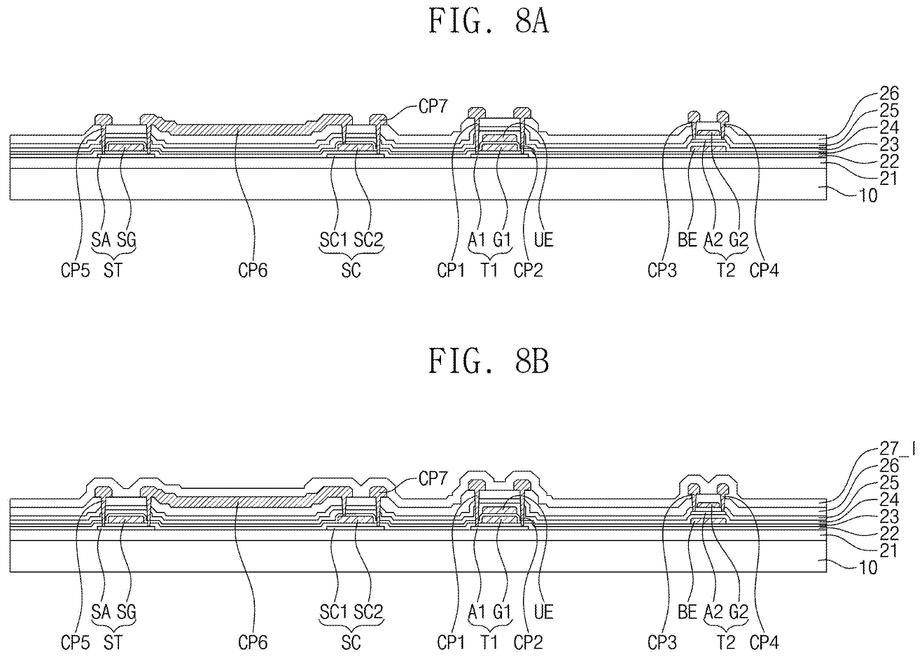

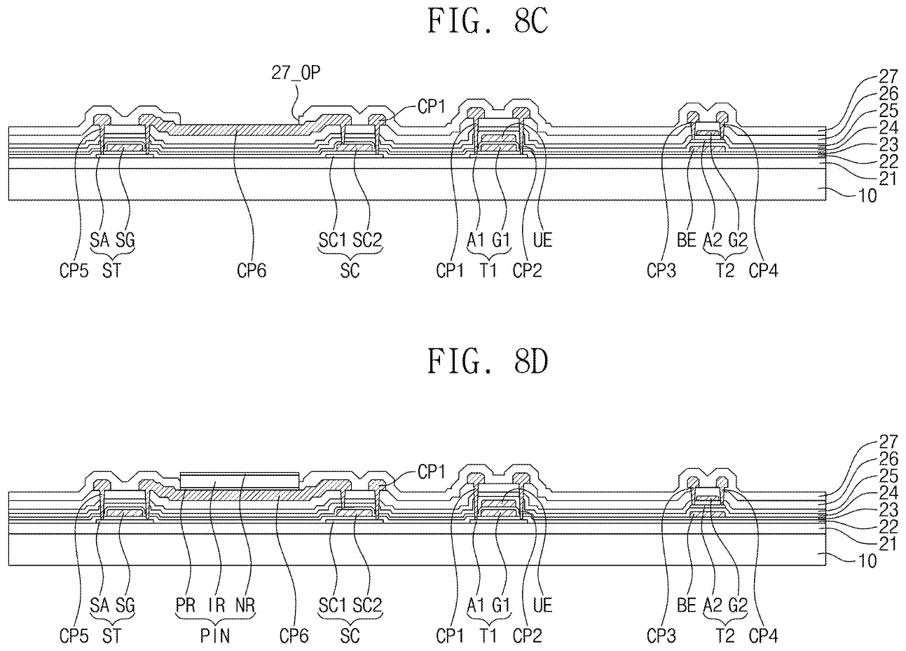

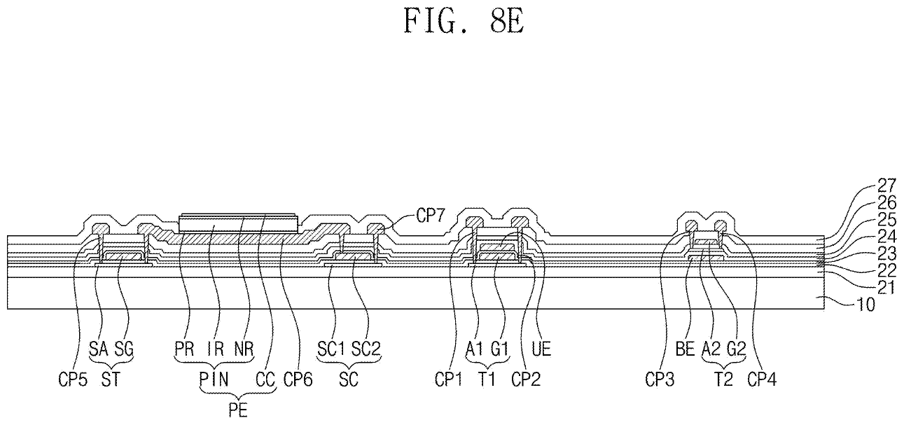

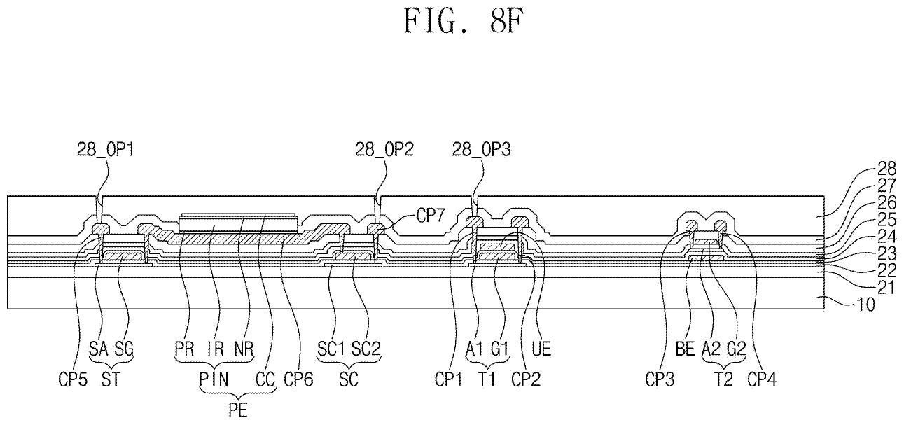

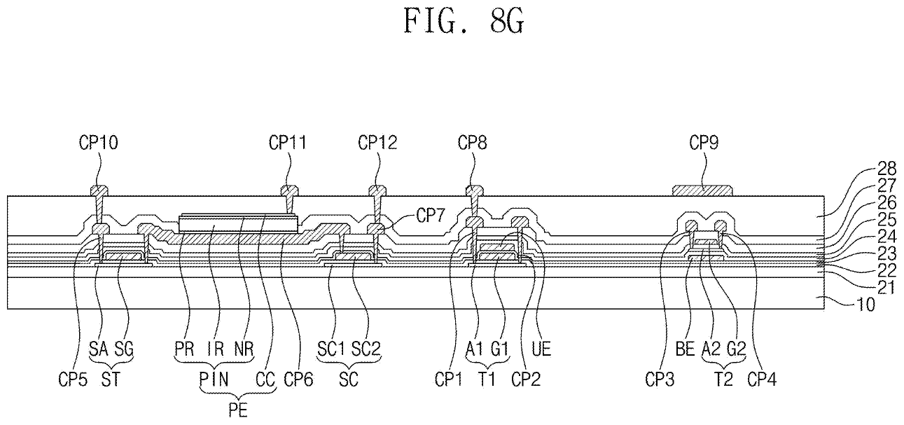

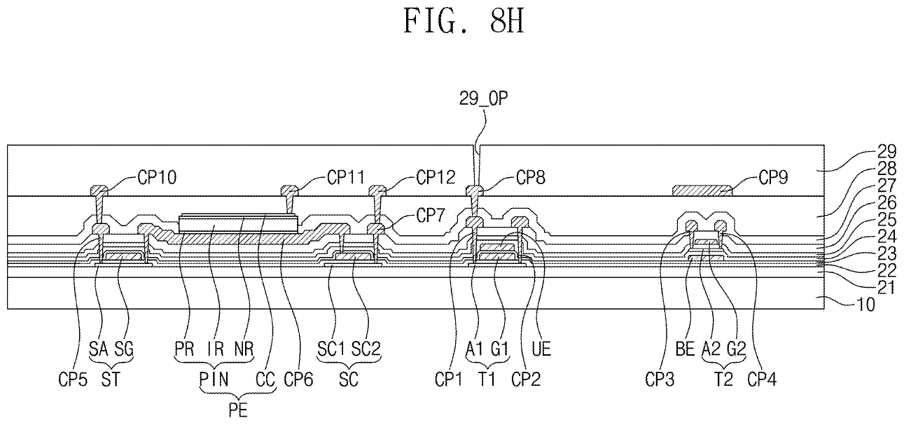

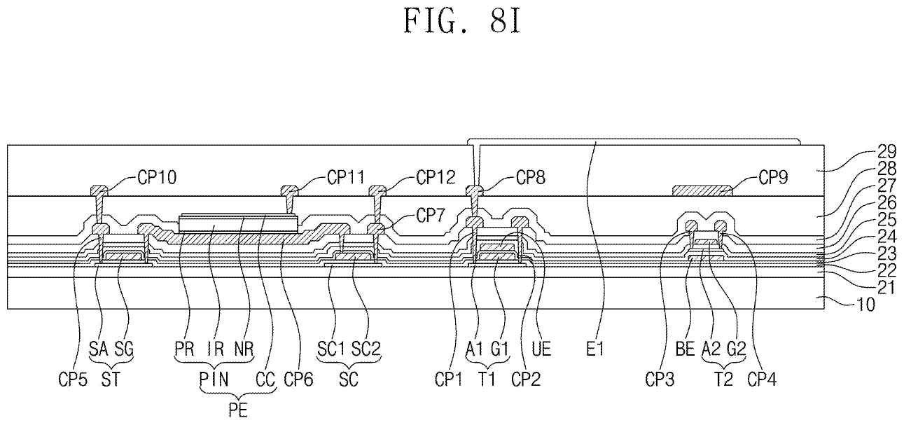

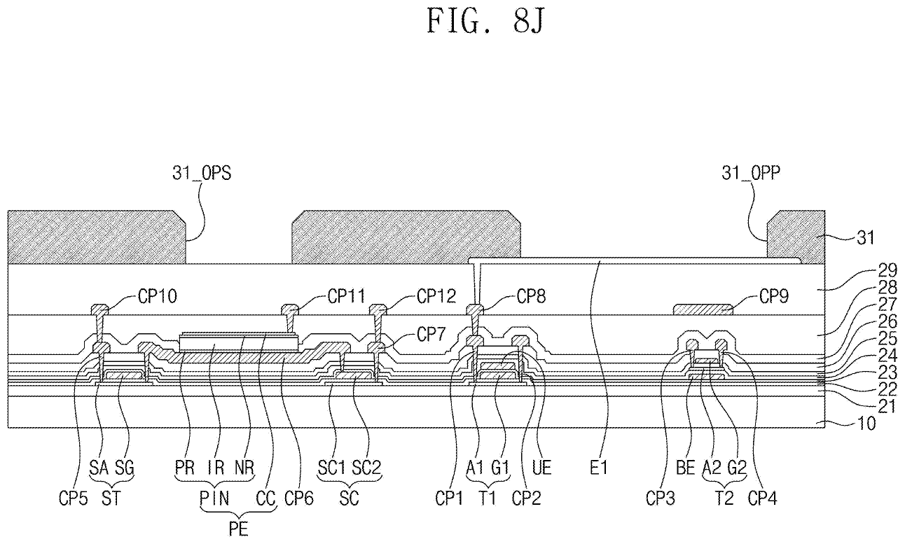

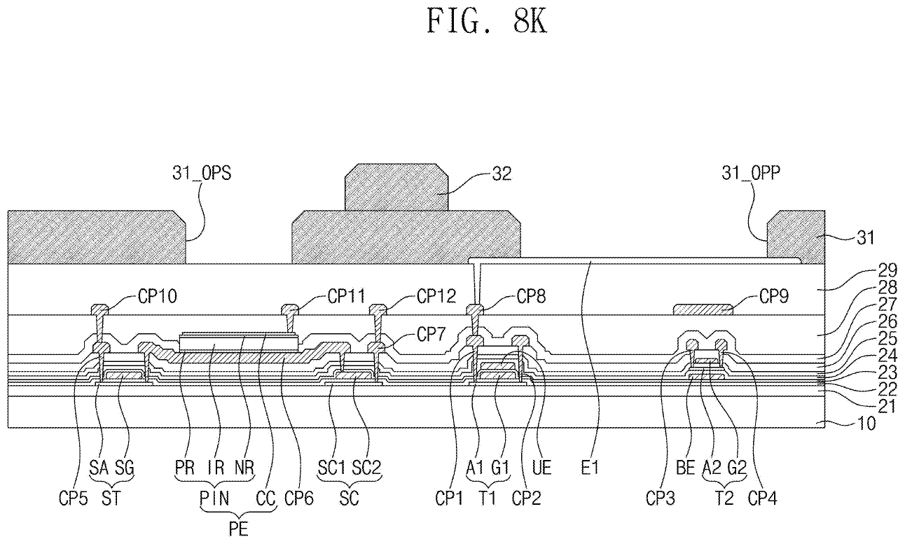

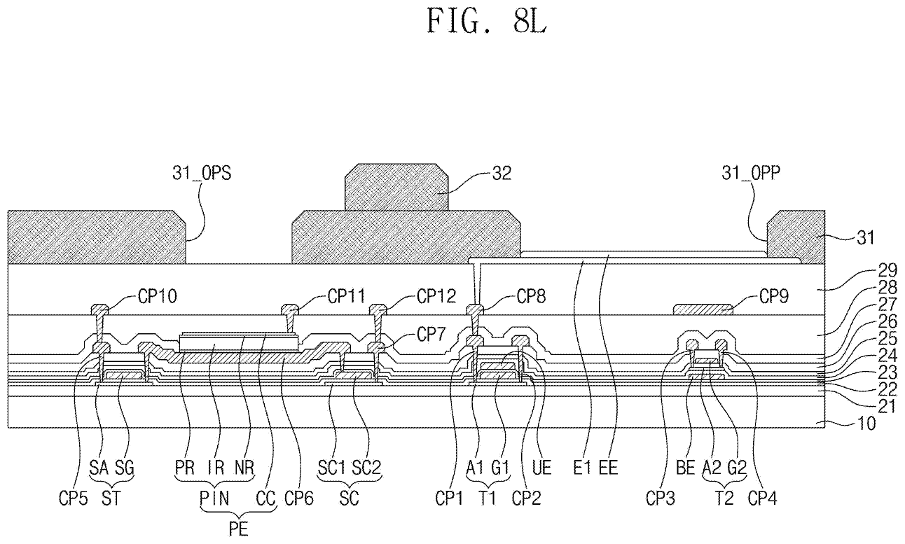

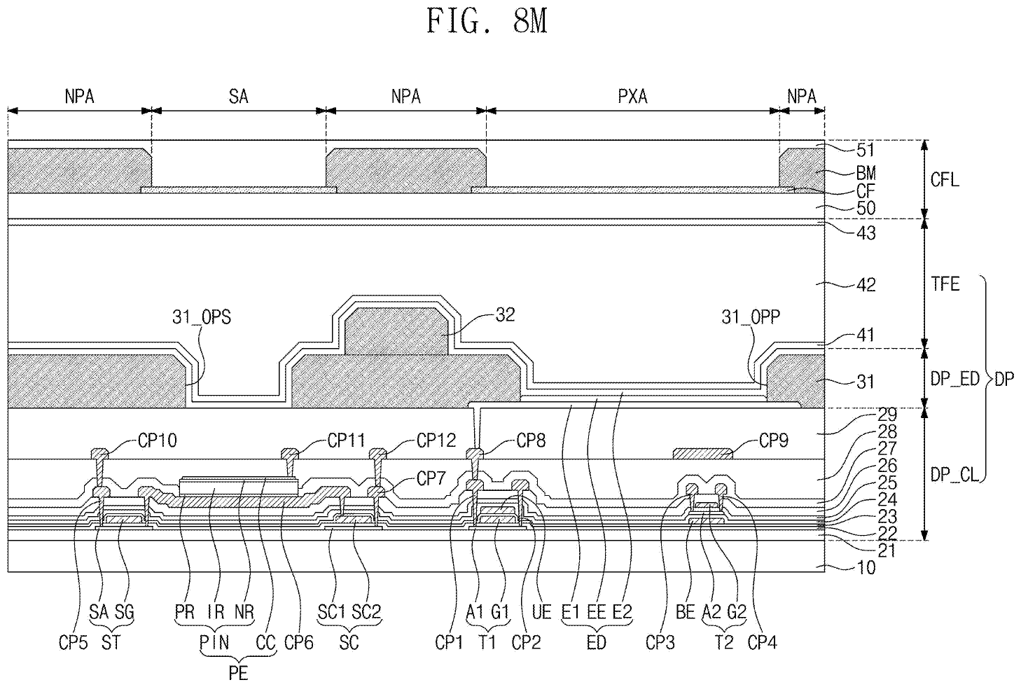

FIGS. 8A to 8M are cross-sectional views of a method of manufacturing the electronic device according to embodiments of the present disclosure. FIGS. 8A to 8M show the electronic device corresponding to the electronic device shown in FIG. 6.

Referring to an embodiment of FIG. 8A, the first pixel transistor T1, the second pixel transistor T2, the sensing transistor ST, and the sensing capacitor SC are formed. In addition, a path to electrically connect the driving elements through the conductive patterns CP1, CP2, CP3, CP4, CP5, and CP6 is formed.

Referring to an embodiment of FIG. 8B, an initial insulating layer 27_I is formed. The initial insulating layer 27_I is formed by depositing an inorganic material. The initial insulating layer 27_I covers the conductive patterns CP1, CP2, CP3, CP4, CP5, and CPG to insulate the conductive patterns CP1, CP2, CP3, CP4, CP5, and CPG from each other.

Referring to an embodiment of FIG. 8C, an opening 27_OP is formed through the initial insulating layer 27_I to form the seventh insulating layer 27. The opening 27_OP is formed through the seventh insulating layer 27, and a portion of the sixth conductive pattern CP6 is exposed.

Referring to an embodiment of FIG. 8D, the photodiode PIN is formed. In an embodiment, the photodiode PIN is formed by sequentially stacking the P-type region PR, the intrinsic region IR, and the N-type region NR. Each of the P-type region PR, the intrinsic region IR, and the N-type region NR is formed by depositing and patterning a semiconductor layer, however, they should not necessarily be particularly limited thereto.

Referring to an embodiment of FIG. 8E, the cathode CC is formed, The cathode CC is formed by depositing and patterning the transparent conductive oxide, however, it should not necessarily be particularly limited thereto. In an embodiment, the cathode CC is directly formed on the photodiode PIN, and thus, the N-type region NR is directly in contact with the cathode CC.

Referring to an embodiment of FIG. 8F, the eighth insulating layer 28 is formed. Openings 28_OPI, 28_OP2, and 28_OP3 are formed through the eighth insulating layer 28 to expose the fifth conductive pattern CP5, the seventh conductive pattern CP7, and the first conductive pattern CP1, respectively. In an embodiment, the eighth insulating layer 28 is formed by depositing and patterning an organic material, however, it should not necessarily be particularly limited thereto.

Referring to an embodiment of FIG. 8G, the conductive patterns CP8, CP9, CP10, CP11, and CP12 are formed. The conductive patterns CP8, CP9, CP10, CP11, and CP12 are filled in the openings or are formed around the openings to form a voltage transmission path.

Referring to an embodiment of FIG. 8H, the ninth insulating layer 29 is formed. An opening 29_,OP is formed through the ninth insulating layer 29 to expose the eighth conductive pattern CP8. In an embodiment, the ninth insulating layer 29 is formed by depositing and patterning an organic material, however, it should not necessarily be particularly limited thereto.

Referring to an embodiment of FIG. 8I, the first electrode E1 of the light emitting element ED is formed, In an embodiment, the first electrode E1 is formed by depositing and patterning a conductive material, however, it should not be limited thereto or thereby.

Referring to an embodiment of FIG. 8J, the pixel definition layer 31 is formed. The first opening 31_OPP is formed through the pixel definition layer 31 to overlap the first electrode E1, and the second opening 31_OPS is formed through the pixel definition layer 31 to overlap the light sensing element PE. In an embodiment, the pixel definition layer 31 is formed by depositing and patterning an insulating material, however, it should not necessarily be particularly limited thereto. In addition, in an embodiment, the pixel definition layer 31 is formed by mixing a black dye and a black pigment.

Referring to an embodiment of FIG. 8K, the spacer 32 is formed. The spacer 32 is formed on the pixel definition layer 31. The spacer 32 is formed of an insulating material and is formed of the same material as or the different material from that of the pixel definition layer 31. In an embodiment, the spacer 32 is formed through a separate process from the pixel definition layer 31, however, it should not necessarily be particularly limited thereto. According to an embodiment, the spacer 32 and the pixel definition layer 31 may be formed through a single process using a halftone mask, and it should not necessarily be particularly limited thereto.

Referring to an embodiment of FIG. 8L, the light emitting layer EE is formed. In an embodiment, the light emitting layer EE is selectively formed in the first opening 31_OP. In an embodiment, the light emitting layer EE is formed through a printing process or a patterning process, however, it should not necessarily be particularly limited thereto, Then, referring to an embodiment of FIG. 8M, follow-up processes are sequentially performed to form the electronic device EA.

According to embodiments of the present disclosure, the light sensing element PE may be formed through the process of forming the circuit layer DP_CL, and thus, an assembly process for the light sensing element PE may be omitted. In addition, since the light sensing element PE may be provided integrally with the display panel DP, the user's convenience may be increased.

Although embodiments of the present disclosure have been described, it is understood that the present disclosure should not be limited to these embodiments b various changes and modifications can be made by one ordinary skilled in the art within the spirit and scope of the present disclosure as hereinafter claimed. Therefore, the disclosed subject matter should not be limited to any single embodiment described herein.

What is claimed:

1. An electronic device comprising:
a base layer;
a pixel definition layer disposed on the base layer, the pixel definition layer including a first opening extending therethrough and a second opening extending therethrough;
a light emitting element disposed on the base layer and overlapping the first opening;
a light sensing element disposed on the base layer and overlapping the second opening, the light sensing element comprising a photodiode and a conductive pattern that directly contacts the photodiode;
a pixel transistor connected to the light emitting element; and
a sensing transistor connected to the light sensing element, wherein the light sensing element is disposed between a layer that the pixel transistor is disposed and a layer that the light emitting element is disposed.

2. The electronic device of claim 1, wherein the conductive pattern comprises a transparent conductive oxide.

3. The electronic device of claim 1, wherein:
the pixel transistor comprises a first semiconductor pattern and a first electrode; and
the sensing transistor comprises:
a semiconductor pattern disposed on a same layer as a layer that the first semiconductor pattern is disposed; and
an electrode disposed on a same layer as a layer that the first electrode is disposed.

4. The electronic device of claim 3, further comprising:
a first conductive pattern connected to the first semiconductor pattern; and
a second conductive pattern connected to a semiconductor pattern of the sensing transistor and disposed on a same layer as a layer that the first conductive pattern is disposed, wherein the photodiode directly contacts the second conductive pattern.

5. The electronic device of claim 4, further comprising a second pixel transistor electrically connected to the pixel transistor, wherein the second pixel transistor comprises a second semiconductor pattern and a second electrode, and the second semiconductor pattern comprises a material different from a material of the first semiconductor pattern:

6. The electronic device of claim 5, wherein the second semiconductor pattern and the second electrode are disposed between the layer that the first electrode is disposed and the layer that the first conductive pattern is disposed:

7. The electronic device of claim 5, further comprising a metal pattern disposed under the second semiconductor pattern, wherein the metal pattern is disposed on a same layer as the layer that the first electrode is disposed.

8. The electronic device of claim 5, wherein the second semiconductor pattern comprises an oxide semiconductor, and the first semiconductor pattern comprises polysilicon.

9. The electronic device of claim 4, further comprising:
a third conductive pattern disposed between the first conductive pattern and the light emitting element and connected to the first conductive pattern and the light emitting element; and
a fourth conductive pattern connected to the light sensing element, wherein the third conductive pattern is disposed on a same layer as a layer that the fourth conductive pattern is disposed.

10. The electronic device of claim 1, further comprising a color filter layer disposed on the light emitting element and comprising a black matrix, wherein the black matrix includes openings extending therethrough to respectively overlap the first opening and the second opening.

11. The electronic device of claim 10, wherein the pixel definition layer comprises a dye or a pigment.

12. The electronic device of claim 10, further comprising an input sensing layer disposed between the color filter layer and the light emitting element.

13. The electronic device of claim 12, wherein the input sensing layer comprises mesh lines connected to each other, and the mesh lines overlap the pixel definition layer when viewed in a plane.

14. An electronic device comprising:
a base layer;
a circuit layer disposed on the base layer and comprising a pixel transistor, a light sensing element, and a sensing transistor connected to the light sensing element;
a pixel definition layer disposed on the circuit layer and comprising a dye or a pigment, the pixel definition layer including a first opening and a second opening and spaced apart from the first opening, the second opening overlapping the light sensing element;
a light emitting element overlapping the first opening;
an encapsulation layer disposed on the light emitting element; and
a color filter layer disposed on the encapsulation layer and comprising a black matrix, the light sensing element comprising:
a photodiode disposed on the sensing transistor; and
a transparent electrode disposed on the photodiode.

15. The electronic device of claim 14, wherein:
the pixel transistor comprises a semiconductor pattern and an electrode; and
the sensing transistor comprises a semiconductor pattern disposed on a same layer as a layer that the semiconductor pattern of the pixel transistor is disposed and an electrode disposed on a same layer as a layer that the electrode of the pixel transistor is disposed.

16. The electronic device of claim 15, further comprising a conductive pattern connected to the semiconductor pattern of the sensing transistor, wherein the photodiode is disposed on the conductive pattern and directly contacts the conductive pattern. 17, The electronic device of claim 16, further comprising a second pixel transistor spaced apart from the pixel transistor and connected to the light emitting element, wherein the second pixel transistor comprises a second semiconductor pattern and a second electrode that are disposed on layers respectively different from layers that the semiconductor pattern and the electrode are disposed.

18. The electronic device of claim wherein the second pixel transistor comprises an oxide semiconductor.

19. The electronic device of claim 14, wherein the pixel transistor and the sensing transistor comprise polysilicon.

20. The electronic device of claim 14, further comprising an input sensing layer disposed between the color filter layer and the encapsulation layer.
